(19) United States
(12) Patent Application Publication
(10) Pub. No.: US 2025/0006658 A1
(43) Pub. Date: Jan. 2, 2025

(54) Three Dimensional Crackstop Interweave Architectural Design Using Supervia.

(71) Applicant: International Business Machines Corporation, Armonk, NY (US)

(72) Inventors: Nicholas Alexander Polomoff, Hopewell Junction, NY (US); Yann Mignot, Slingerlands, NY (US); Brent A. Anderson, Jericho, VT (US); Lawrence A. Clevenger, Saratoga Springs, NY (US)

(21) Appl. No.: 18/216,328

(22) Filed: Jun. 29, 2023

(51) Int. Cl. H01L 23/00; H01L 21/768; H01L 23/522; H01L 23/528

(52) U.S. Cl. CPC H01L 23/562; H01L 21/76816; H01L 23/5226; H01L 23/528

(57) ABSTRACT

A structure comprising: metal lines and viabars that surround a periphery of an active area of a semiconductor device; at least one viabar that extends through multiple layers of the semiconductor device, wherein the at least one viabar connects a metal line of one layer of the structure with a metal line of another layer of the structure; and a connection viabar that terminates at a metal line of a layer between the one layer of the structure and the another layer of the structure, wherein a thickness of the connection viabar is less than a thickness of the at least one viabar.

### BACKGROUND

The exemplary embodiments described herein relate generally to semiconductor device design and integrated circuit design, and more specifically, to a three dimensional crackstop interweave architectural design using a supervia.

As semiconductor technology nodes progress, the dielectric thickness of layers of these respective technologies continually decrease in thickness. Consequently the mechanical barrier crackstop structures built into these layers also experience a decrease in their respective structural element sizes.

The current state of the art semiconductor manufacturing processing techniques and process flows of layer by layer fabrication result in the creation of completely aligned and in sync interfaces completely lined up in one direct path between different levels of the BEOL dielectric stack and the respective metallic structures built into these levels. If during processing one interface becomes compromised or weakened, this weakened interface could potentially result in an energetically favorable preferential growth and propagation path for an impinging crack to exploit. Also, reduction of the dielectric material's thickness or height (Z) of each of the BEOL dielectric stack's layers will result in decreasing strength and robustness of the crackstop structure. As semiconductor technology advances and the nodes decrease in size (as described by Moore's Law), the respective thickness of the dielectric layers comprising the BEOL dielectric stack of the respective microchips also undergoes a decrease in size.

This decrease in BEOL dielectric layer thickness reduces the efficacy, performance and strength of the crackstop design, in that the same crackstop design that once exhibited excellent crack stopping properties in older mature technologies having thicker BEOL dielectric layers, may have its robustness, strength and overall performance impacted and reduced as these BEOL dielectric layer thicknesses shrink with respect to the advancing technology node. When a crackstop design and architecture once exhibiting superior crackstopping properties and mechanical strength in older technology nodes is placed into a more advanced semiconductor technology node build that is comprised of thinner BEOL dielectric layer thicknesses, its strength and mechanical robustness will be reduced. Consequently, the crackstop design will exhibit less overall efficacy at stopping impinging crack breaches and there will be a higher probability of failure of the crackstop design.

Expanding or widening of the X and Y dimensions of the viabars of the crackstop design may not work at mitigating the weakening of the overall crackstop design with respect to shrinking dielectric layer thicknesses (Z) of advancing semiconductor node technologies. While thickening of the X and Y dimension of the viabar design will improve the strength of the crackstop design, such design alterations in the 2D plane of X and Y might not be sufficient enough to offset the reduction of the structures' thickness or height and the impact this reduction has on the crackstop's overall mechanical strength. Therefore, design changes in the Z dimension would be beneficial and necessary. Increases to width of X and Y dimensions could also potentially result in an increased strain profile within the respective redesigned layer resulting in the layer being more susceptible to crack initiation.

Plastic deformation and fracture-based modes of failure are dependent and directly correlate to BEOL dielectric layer thickness and the interfaces between the respective BEOL dielectric layers. As layer thicknesses decrease there is a marked drop in plasticity and an increase on shear and fracture.

Thus, decreasing layer thicknesses (Z direction) results in a weakening of crackstop designs. As thicknesses shrink while keeping the crackstop design the same, a high strain appears indicating a higher likelihood for cracking to appear and weaker overall crackstop performance.

With technology scaling, the propensity of crack propagation in the crackstop increases post dicing. The solution to this, which solution is implemented by the examples described herein, is to increase metal portions to extend across multiple layers and thicknesses effectively, invoking or creating the thicker metal designs but in thinner layer technologies.

### SUMMARY

In one aspect, a structure includes: metal lines and viabars that surround a periphery of an active area of a semiconductor device; at least one viabar that extends through multiple layers of the semiconductor device, wherein the at least one viabar connects a metal line of one layer of the structure with a metal line of another layer of the structure; and a connection viabar that terminates at a metal line of a layer between the one layer of the structure and the another layer of the structure, wherein a thickness of the connection viabar is less than a thickness of the at least one viabar.

In another aspect, a method includes: forming at least one space through multiple layers of dielectric material, the at least one space terminating at a metal line of a first layer of dielectric material; forming at least one viabar within the at least one space; connecting a metal line of a second layer of dielectric material to the at least one viabar; and forming a connection viabar that terminates at a metal line of a layer between the first layer of dielectric material and the second layer of dielectric material, wherein a thickness of the connection viabar is less than a thickness of the at least one viabar; wherein the at least one viabar, the metal line of the first layer, and the metal line of the second layer surround a periphery of an active area of a semiconductor device.

In another aspect, a mechanical crackstop barrier includes viabar mesh patterns that extend across multiple back end of line layers and terminate on different metal levels so that a seam of a metal line to a viabar is staggered through a back end of line dielectric stack height.

### BRIEF DESCRIPTION OF THE DRAWINGS

The foregoing and other aspects of exemplary embodiments are made more evident in the following Detailed Description, when read in conjunction with the attached Drawing Figures, wherein:

FIG. 1 illustrates decreasing thickness of advancing technology nodes;

FIG. 2 shows a semiconductor device design, based on the examples described herein, compared with another design;

FIG. 3A shows a semiconductor device design with an impinging crack;

FIG. 3B shows a semiconductor device design that halts a crack propagation growth path;

FIG. 4 shows a semiconductor device crackstop design;

FIG. 5 shows a semiconductor device crackstop design that incorporates a supervia net;

FIG. 6 shows a semiconductor device crackstop design with supervias interweaved within metal plates;

FIG. 7 shows a semiconductor device crackstop design with staggered supervia structures;

FIG. 8 shows a semiconductor device crackstop design with multiple height supervias interweaved to create a cage-like interwoven three-dimensional structure;

FIG. 9 depicts various schematics of the designs described herein for small node technologies;

FIG. 10 shows an example process flow to form a crackstop design as described herein;

FIG. 11 depicts schematics of the designs described herein for small node technologies;

FIG. 12 depicts various design schematics having a viabar through viabar pattern that forms a cage-like interwoven three-dimensional structure;

FIG. 13 is an example process flow to form a device having mixed viabar heights;

FIG. 14 shows various examples of crackstop designs, based on the examples described herein;

FIG. 15 shows examples of designs for implementing an interweave crackstop cage-like interwoven three-dimensional structure, based on the examples described herein; and

FIG. 16 is a logic flow diagram to implement a method, based on the examples described herein.

### DETAILED DESCRIPTION

The term “exemplary” is used herein to mean “serving as an example, instance, or illustration.” Any embodiment described herein as “exemplary” is not necessarily to be construed as preferred or advantageous over other embodiments. All of the embodiments described in this Detailed Description are exemplary embodiments provided to enable persons skilled in the art to make or use the invention and not to limit the scope of the invention which is defined by the claims.

Described herein is a mechanical metallic wall composed of metal lines and/or wires and viabars that surround the periphery of a semiconductor device's active area that protect the device region from cracking and delamination. This cracking and delamination can occur during the dicing of the semiconductor die out of its wafer form. A crack or delamination could potentially also occur during operating life of the semiconductor die under different environmental and CPI related stresses (thermal, vibrations, etc.). Further described herein are supervia and skipvia structures integrated into the overall macroscopic design. Their inclusion in the overall crackstop design gives the structure larger viabars and can be interwoven to create a three dimensional crackstop architecture structure.

The use and integration of supervia bar structures (that traverse through two or more dielectric layers) into the crackstop's macroscopic design increases the crackstop design's mechanical strength and performance by giving the crackstop the same or similar size viabars of previous technology nodes, but integrated into thinner advance technology node BEOL layers.

Supervia structures can also be interwoven along with discrete single level viabar designs within the crackstop's overall design, thereby breaking up and dispersing any linear vulnerable metal to metal interfaces that cracks could leverage to break through the crackstop structure. These interweave designs have a superior fortified tie-down mechanical adhesive property when compared to the traditional single level, brick by brick design of traditional crackstops.

Thus, described herein is a mechanical crackstop barrier that is comprised of viabar mesh patterns that extend across multiple BEOL layers and terminate or land on different metal levels so that the seam interfaces of metal line to viabar is staggered through the BEOL dielectric stack height. The supervias and skipvias are used for a mechanical function. The extended viabar patterns can be interwoven to form a mechanical cage-like crackstop structure.

The structure described herein may be used as advancing node technology dielectric BEOL layer thicknesses continue to shrink and more complex three-dimensional integration builds become more intricate and sophisticated where the efficacy of the traditional crackstop diminishes. The herein described crackstop structures enhance the crackstop strength and performance with respect to CPI related issues.

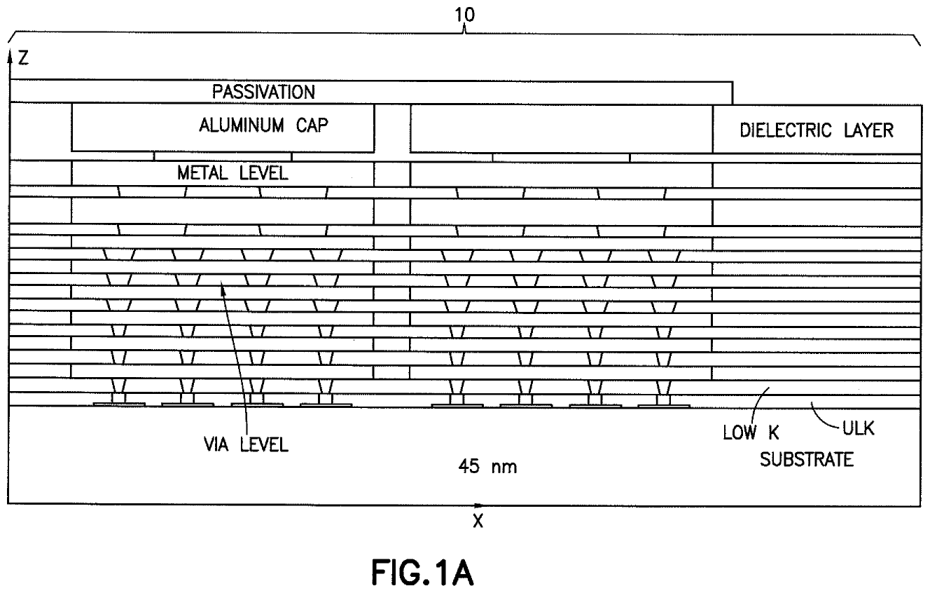

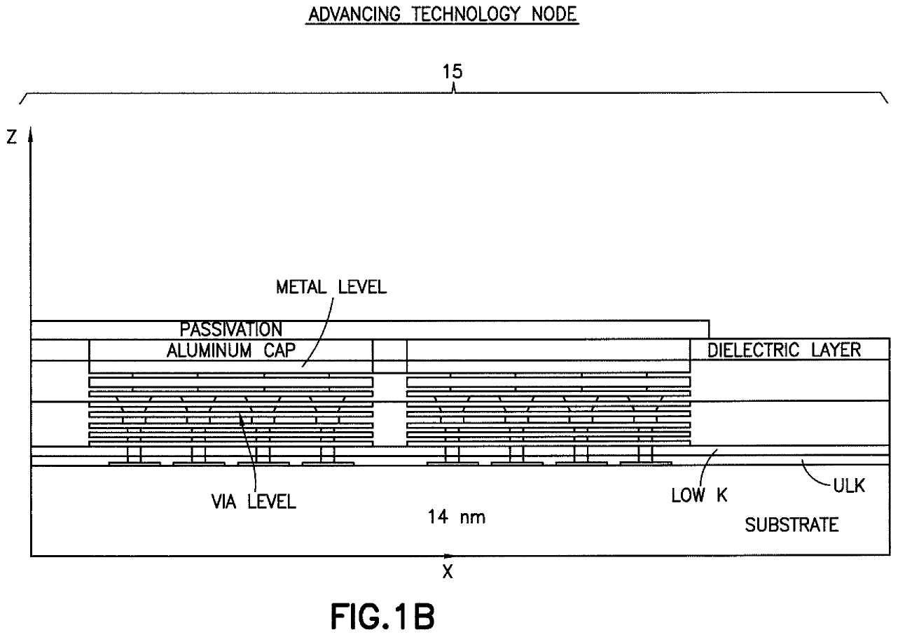

FIG. 1 illustrates decreasing thickness of advancing technology nodes. The overall thickness of the semiconductor builds is decreasing with advancing technology nodes. Device 10 has a passivation layer, an aluminum cap, a metal level, a via level, dielectric layers, a low K layer, and a ULK layer. Device 15 has a passivation layer, an aluminum cap, a metal level, a via level, dielectric layers, a low K layer, and a ULK layer, but with a lower overall thickness relative to device 10.

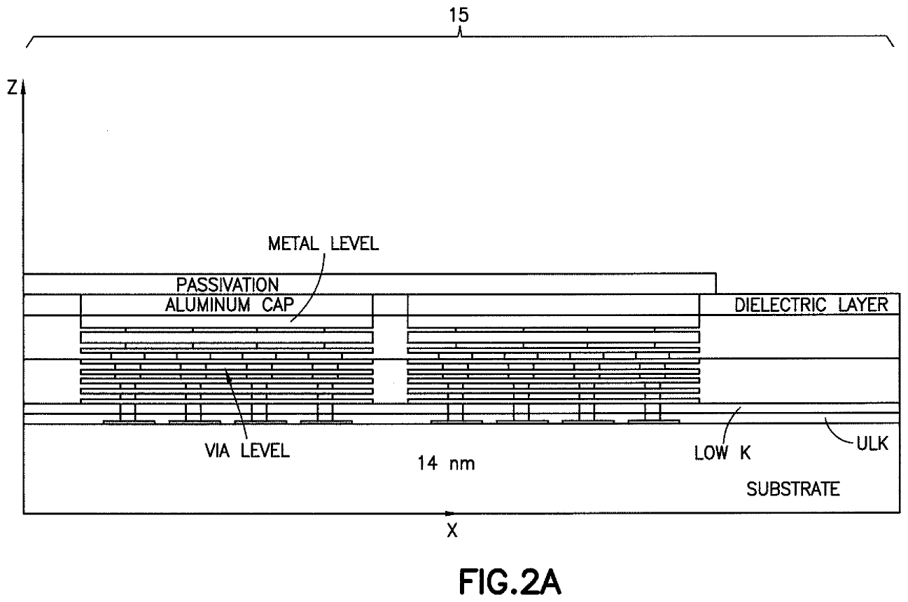

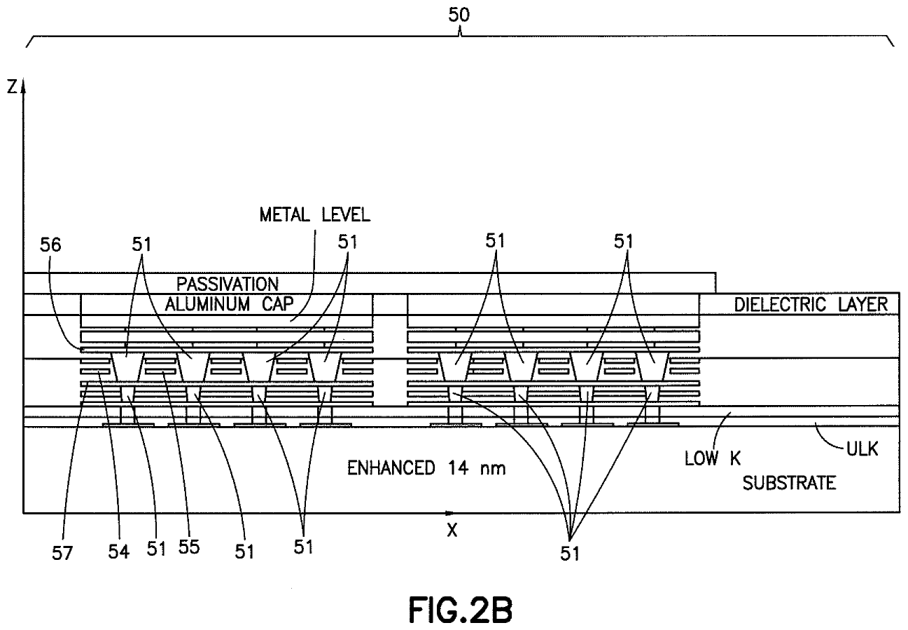

FIG. 2 shows a semiconductor device 50 implementing an enhanced design, based on the examples described herein, compared with a design of device 15. Shown are the supervia or skipvia bar structures (51) that span (e.g. extend through) multiple layers of the device, are interwoven between metal plates of the device 50, and connect metal layers and or metal plates of the device 50. For example, one (51) of the skipvia bars (51) is between metal plates 54, and 55, and connects metal layer 56 to metal layer 57.

The supervias or skipvia bars (51) of the device 50 are larger in size relative to standard viabars, and the supervias or skipvia bars (51) extend across multiple layers and thicknesses to evoke and create a thicker metal design within thinner layers. The new design of the semiconductor device 50 invokes the robustness of previous mature designs (such as the design of structure 15), but within the matrix of newer thinner dielectric thicknesses.

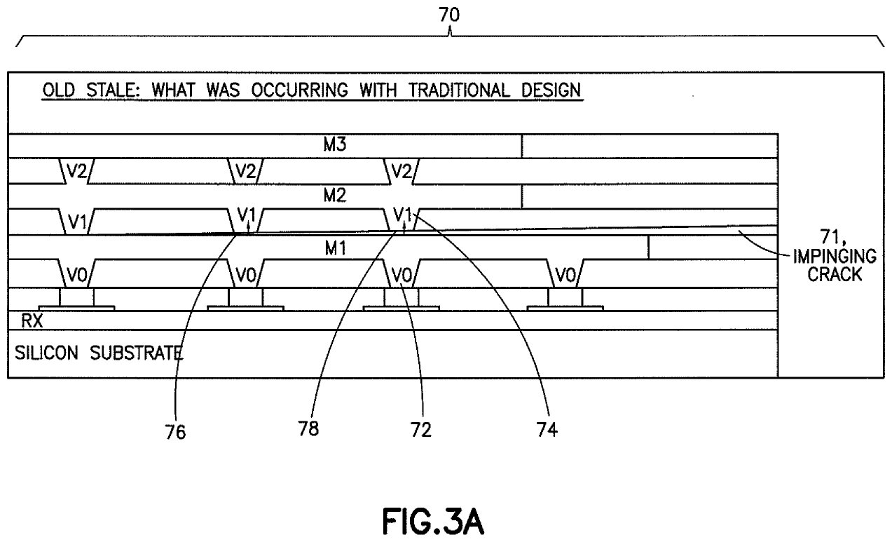

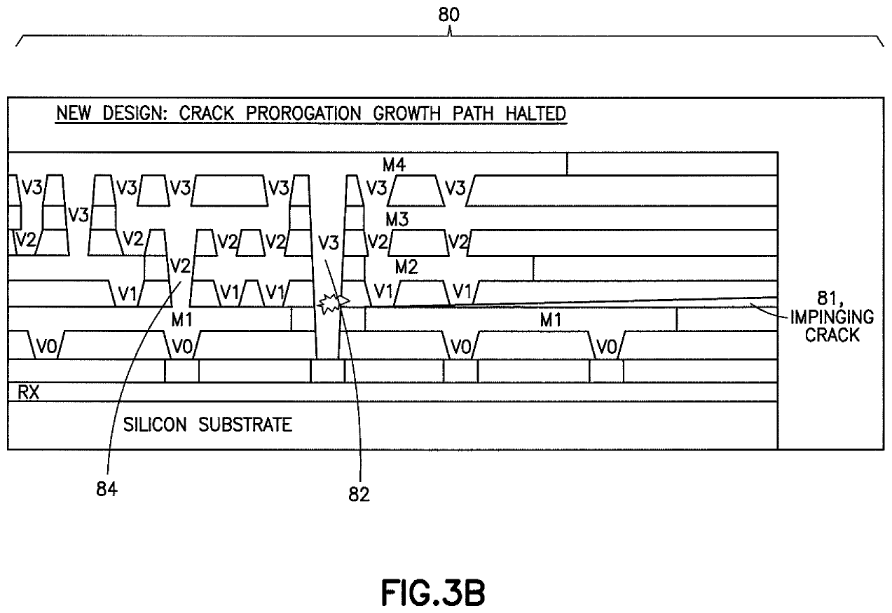

FIG. 3A shows a semiconductor device design 70 and an impinging crack 71 within the structure. FIG. 3B shows a semiconductor device design 80 that halts a crack propagation growth path of an impinging crack 81. Together FIG. 3A and FIG. 3B show the concept at work. In particular, the impinging crack 81 is halted at least due to supervia or skip via bars (82, 84) spanning (e.g. extending through) multiple layers within the structure. The design 80 as herein described breaks up the direct line of sight interfaces, such as interfaces (72, 74), removing an aligned weak interface. The design 80 uses large viabar heights and thicknesses which increase crackstop strength and robustness. Crack propagation is directed towards and follows the lowest energy path. Removing the weak interface junction (76, 78) that was perfectly aligned breaks up the preferential propagation growth path of the crack (71, 81).

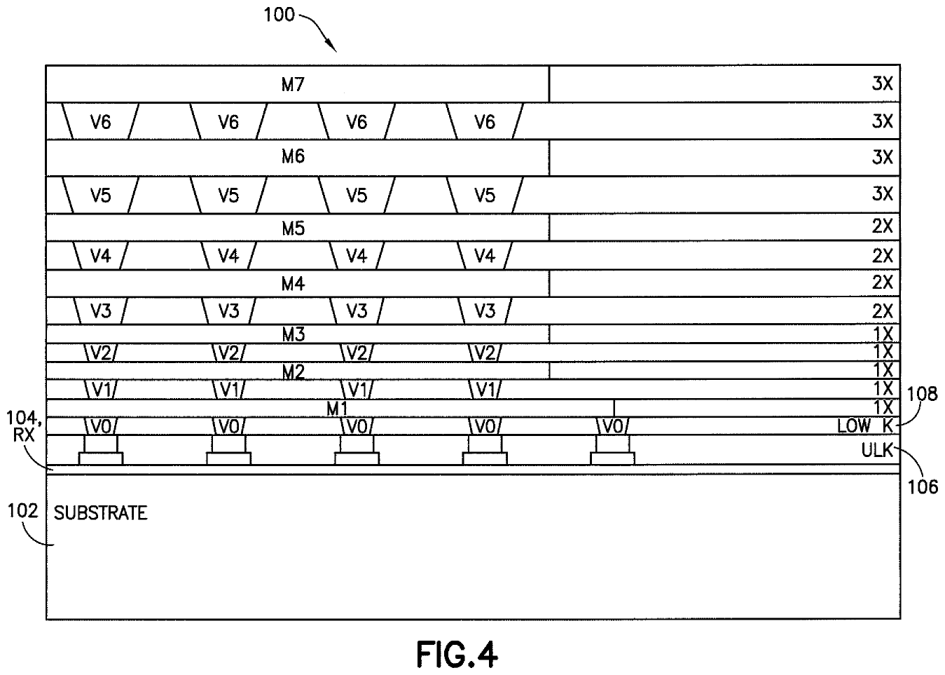

FIG. 4 shows a semiconductor device 100 with a crackstop design. Viabars (V0) within a low K dielectric layer 108 connect metal layer M1, which is formed within a 1X-sized layer (X being a width or length value e.g. thickness), to active layer 104 through an ultra low-K layer 106, which active layer 104 is connected to substrate 102. Viabars (V1) within a 1X-sized layer connect metal layer M1 to metal layer M2, which is formed within a 1X-sized layer. Viabars (V2) within a 1X-sized layer connect metal layer M2 to metal layer M3, which is formed within a 1X-sized layer. Viabars (V3) within a 2X-sized layer connect metal layer M3 to metal layer M4, which is formed within a 2X-sized layer. Viabars (V4) within a 2X-sized layer connect metal layer M4 to metal layer M5, which is formed within a 2X-sized layer. Viabars (V5) within a 3X-sized layer connect metal layer M5 to metal layer M6, which is formed within a 3X-sized layer. Viabars (V6) within a 3X-sized layer connect metal layer M6 to metal layer M7, which is formed within a 3X-sized layer.

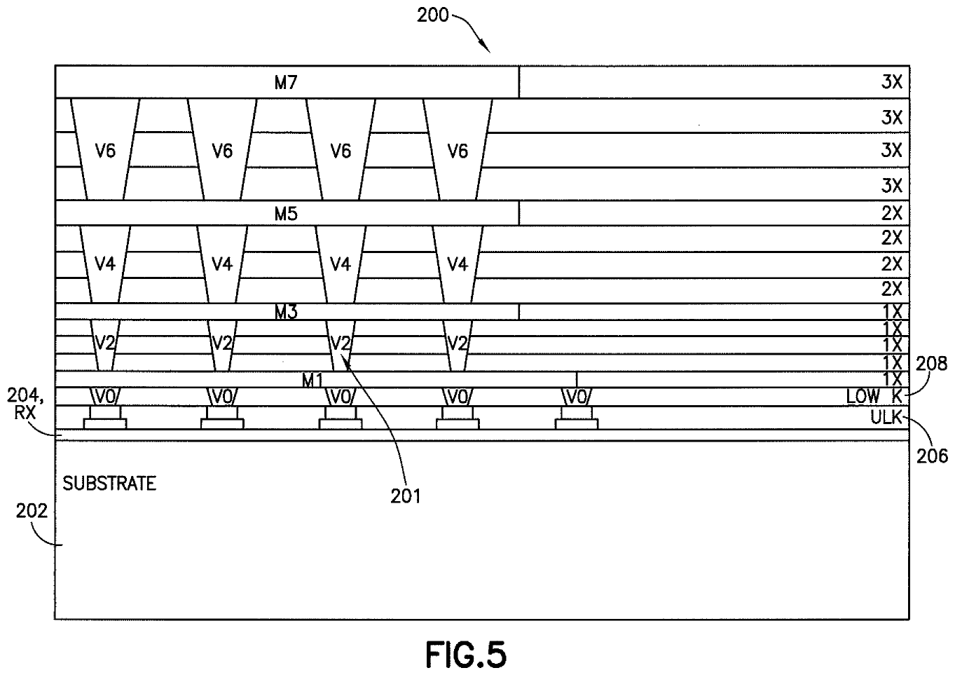

FIG. 5 shows a semiconductor device 200 having a crackstop design that incorporates a supervia net 201. The design includes tall and thick viabars (V2, V4, V6) used for a mechanical purpose. Viabars (V0) within a low K dielectric layer 208 connect metal layer M1, which is formed within a 1X-sized layer (X being a width or length value e.g. thickness), to active layer 204 through an ultra low-K layer 206, which active layer 204 is connected to substrate 202. Viabars (V2) that span (e.g. extend through) three 1X-sized layers connect metal layer M1 to metal layer M3, which is formed within a 1X-sized layer. Viabars (V4) that span (extend through) three 2X-sized layers connect metal layer M3 to metal layer M5, which is formed within a 2X-sized layer. Viabars (V6) that span three 3X-sized layers connect metal layer M5 to metal layer M7, which is formed within a 3X-sized layer. Metal layers (M2, M4, M6) within the structure 100 are not within structure 200.

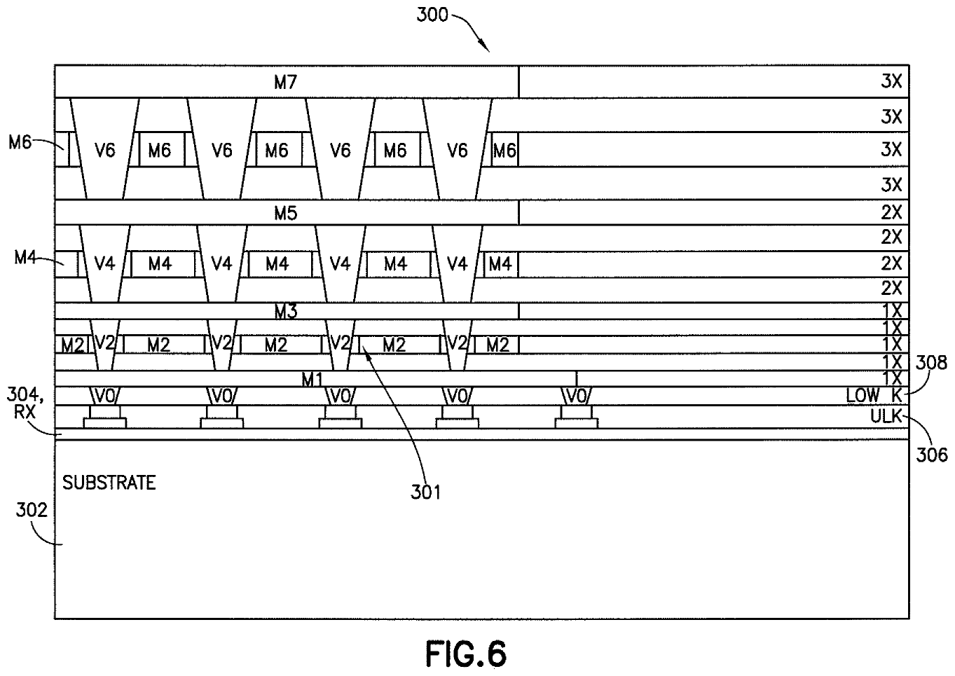

FIG. 6 shows a semiconductor device 300 having a crackstop design with supervia interweaved metal plates, with such interweaving depicted as item 301. Metal plates (each labeled M2), are interweaved between the viabars (V2), or conversely the viabars (V2) are interweaved between the metal plates (M2), where the viabars (V2) span (e.g. extend through) three 1X-sized layers and that connect metal layer M1 to metal layer M3. Metal plates (each labeled M4) are interweaved between the viabars (V4), or conversely the viabars (V4) are interweaved between the metal plates (M4), where the viabars (V4) span three 2X-sized layers and that connect metal layer M3 to metal layer M5. Metal plates (each labeled M6), are interweaved between the viabars (V6), or conversely the viabars (V2) are interweaved between the metal plates (M2), where the viabars (V6) span three 3X-sized layers and that connect metal layer M5 to metal layer M7. Even though the metal interwoven plates (M6, M4 and M2) appear segmented in the cross sectional picture of FIG. 6, each of the metal plates (M2, M4, M6) is actually one continuous plate with holes in them that the super viabars (V2, V4, V6) interweave through, which is shown in the later 3D figures provided herein, including structure 1420, structure 1524, structure 1550, and structure 1808.

Similar to the semiconductor device 200, the semiconductor device 300 also has a supervia net incorporated into the crackstop design. The design of semiconductor device 300 includes tall and thick viabars (V2, V4, V6) used for a mechanical purpose. Viabars (V0) within a low K dielectric layer 308 connect metal layer M1, which is formed within a 1X-sized layer (X being a width or length value e.g. thickness), to active layer 304 through an ultra low-K layer 306, which active layer 304 is connected to substrate 302. Viabars (V2) that span (e.g. extend through) three 1X-sized layers connect metal layer M1 to metal layer M3, which is formed within a 1X-sized layer. Viabars (V4) that span three 2X-sized layers connect metal layer M3 to metal layer M5, which is formed within a 2X-sized layer. Viabars (V6) that span three 3X-sized layers connect metal layer M5 to metal layer M7, which is formed within a 3X-sized layer.

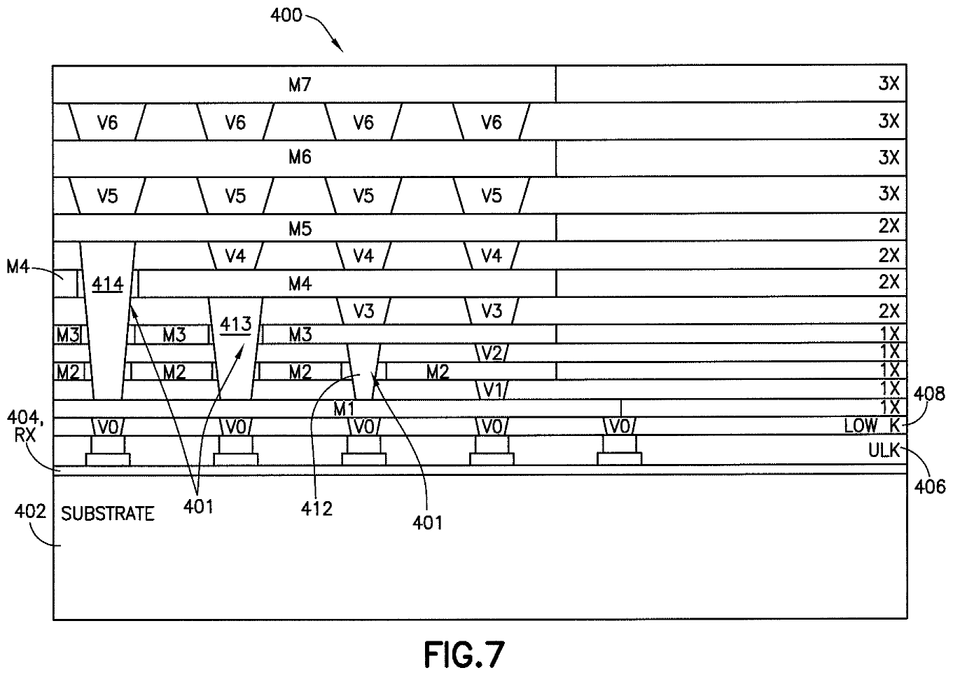

FIG. 7 shows a semiconductor device 400 having a crackstop design with staggered supervia structures. FIG. 7 has a staggering (401) of supervia structures with differing origin points or termination points on the metal plates of the crackstop design. The staggering is such that viabar 414 is larger in at least the Z direction than viabar 413 which is larger in at least the Z direction than viabar 412. Viabar 414 is interweaved between two metal plates M2, two metal plates M3, and two metal plates M4. Viabar 414 originates or terminates at metal layer M5 similar to viabars (V4). Viabar 414 connects metal layer M1 to metal layer M5, and spans (e.g. extends through) four 1X-sized layers and three 2X-sized layers. Viabar 413 is interweaved between two metal plates M2 and two metal plates M3. Viabar 413 originates or terminates at metal layer M4 similar to viabars (V3). Viabar 413 connects metal layer M1 to metal layer M4, and spans four 1X-sized layers and one 2X-sized layer. Viabar 412 is interweaved between two metal plates M2 and two metal plates M3. Viabar 412 originates or terminates at metal layer M3 similar to viabar (V2). Viabar 412 connects metal layer M1 to metal layer M3, and spans three 1X-sized layers.

The crackstop design of structure 400 combines the supervia net crackstop design of structure 200 with the supervia interweaved metal plate crackstop design of structure 300, as well as elements of the structure 100. The design of semiconductor device 400 includes tall and/or thick viabars (412, 413, 414) used for a mechanical purpose. Viabars (V0) within a low K dielectric layer 408 connect metal layer M1, which is formed within a 1X-sized layer (X being a width or length value e.g. thickness), to active layer 404 through an ultra low-K layer 406, which active layer 404 is connected to substrate 402. Viabar (V1) within a 1X-sized layer connects metal layer M1 to a metal plate M2, which is formed within a 1X-sized layer. Viabar (V2) within a 1X-sized layer connects the metal plate M2 to a metal plate M3, which is formed within a 1X-sized layer. Viabars (V3) within a 2X-sized layer connect one of the metal plates (M3) to one of the metal plates (M4), which is formed within a 2X-sized layer. Viabars (V4) within a 2X-sized layer connect one of the metal plates (M4) to metal layer M5, which is formed within a 2X-sized layer. Viabars (V5) within a 3X-sized layer connect metal layer M5 to metal layer M6, which is formed within a 3X-sized layer. Viabars (V6) within a 3X-sized layer connect metal layer M6 to metal layer M7, which is formed within a 3X-sized layer.

In FIG. 7, even though the metal interwoven plates (M2, M3, M4) appear segmented in the cross sectional picture of FIG. 7, each of the metal plates (M2, M3, M4) is actually one continuous plate with holes in them that the super viabars (412, 413, 414) interweave through, which is shown in the later 3D figures provided herein, including structure 1420, structure 1524, structure 1550, and structure 1808.

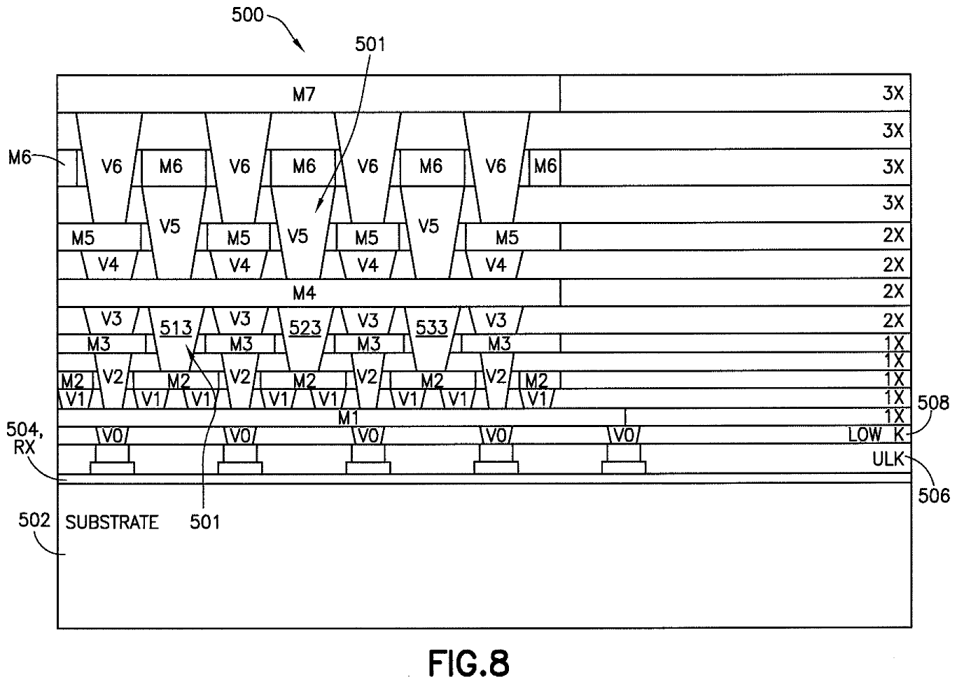

FIG. 8 shows a semiconductor device 500 having a crackstop design with multiple height supervias interweaved to create an interwoven three-dimensional structure, with item 501 referring to the three-dimensional interwoven structure. Viabars (V2) are interweaved between metal plates (M2) that are formed within a 1X-sized layer, span (e.g. extend through) three 1X-sized layers, and each connect a metal plate (M3) formed within a 1X-sized layer to metal layer M1 formed within a 1X-sized layer. Viabars (513, 523, 533) span two 1X-sized layers and one 2X-sized layer, are each interweaved between two metal plates (M3), and each connect a metal plate M2 formed within a 1X-sized layer to metal layer M4 formed within a 2X-sized layer. Viabars (513, 523, 533) originate or terminate at the M4 layer, similar to viabars (V3). Viabars V5 each connect metal layer M4 to a metal plate M6 formed within a 3X sized layer, and each of the viabars (V5) span two 2X-sized layers and one 3X-sized layer. Viabars V6 each connect metal layer M7 formed within a 3X-sized layer to a metal plate M5 formed within a 2X-sized layer, and each span three 3X-sized layers.

In FIG. 8, viabars (V0) within a low K dielectric layer 508 connect metal layer M1, which is formed within a 1X-sized layer (X being a width or length value e.g. thickness), to active layer 504 through an ultra low-K layer 506, which active layer 504 is connected to substrate 502. Each of the viabars (V1) within a 1X-sized layer connect metal layer M1 to a metal plate M2, which is formed within a 1X-sized layer. Each of the viabars (V3) within a 2X-sized layer connect one of the metal plates (M3) that are formed within a 1X-sized layer to metal layer M4 formed within a 2X-sized layer. Each of the viabars (V4) within a 2X-sized layer connect one of the metal plates (M5) formed within a 2X-sized layer to metal layer M4.

In FIG. 8, even though the metal interwoven plates (M2, M3, M5, M6) appear segmented in the cross sectional picture of FIG. 8, each of the metal plates (M2, M3, M5, M6) is actually one continuous plate with holes in them that the super viabars (V2, 513, 523, 533, V5, V6) interweave through, which is shown in the later 3D figures provided herein, including structure 1420, structure 1524, structure 1550, and structure 1808.

In the embodiments shown in FIG. 4, FIG. 5, FIG. 6, FIG. 7, FIG. 8, and elsewhere herein, even though the sizes of the layers are indicated as being 1×, 2×, 3×, in terms of thicknesses of the layers in the Z direction, the size or thickness of the layers may have different scaling factors, for example, the 1X-sized layers correspond to 1.1X-sized layers, the 2X-sized layers correspond to 2.5X-sized layers, the 3X-sized correspond to 3.3X-sized layers, etc. Further the 1X-sized layers, the 2X-sized layers, and the 3X-sized layers may be dielectric layers or back end of line (BEOL) layers. Each of the substrates (102, 202, 302, 402, 502) may be a silicon substrate. Furthermore each of the 1X-sized layers, the 2X-sized layers, and the 3X-sized layers may have varied sizes. For example, one layer depicted as having a size of 1× may be of size 1.1×, and another layer depicted as having a size of 1× may be of size 1.2× (and similarly for the layers depicted as having a 2X-size and a 3X-size).

Accordingly, described herein is a mechanical metallic wall composed of metal lines or wires and viabars that surround the periphery of a semiconductor device's active area that has supervia or skipvia bar structures integrated into the overall macroscopic design. The supervia or skipvia bar structures create a three-dimensional crackstop architecture by leveraging a thickness (Z) element of the design. The supervia or skipvia bar structures are integrated into the crackstop design to create a purely mechanical structure with no electrical properties or impact to device structures. Inclusion of the supervia or skipvia bar structures into the crackstop design improves the overall strength of the macroscopic build.

The supervia or skipvia bar structures start, pass, and/or extend through and terminate on one or multiple levels of the BEOL dielectric stack. The supervia or skipvia bar structures can be aligned and stack in sequence with the BEOL of the dielectric stack. The starting and termination points of the supervia or skipvia bar structures within the BEOL dielectric stack can be staggered in varying subsets of the layers (odd or even). The supervia or skipvia bar structures can be constructed in the crackstop design along and adjacent to standard vias and viabars. The supervia or skipvia bar structures can be interwoven within and between metal plates, and standard single level viabar structures of the crackstop design together to create a three-dimensional interlaced metallic barrier structure. The supervias or skipvia bars can bypass metal plate line levels.

The problem the examples described herein address is that cracks produced during dicing up of individual dies from a substrate can result in catastrophic failures during reliability testing and overall performance and life expectancy of products. Current crackstop designs are built up layer by layer through the use of hundreds of masks. Building up the crackstop design in this manner creates potentially weak interfaces and potential misalignments and unlanded structures.

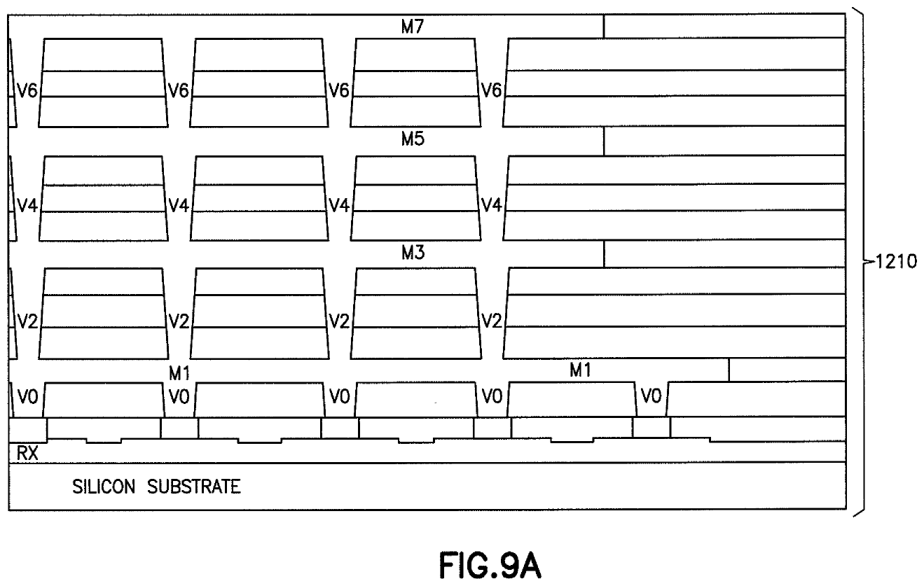

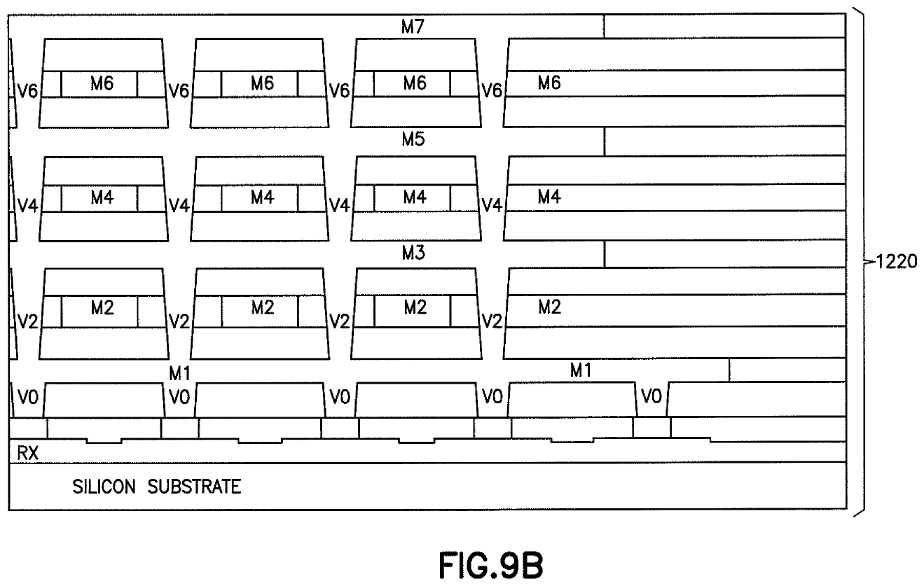

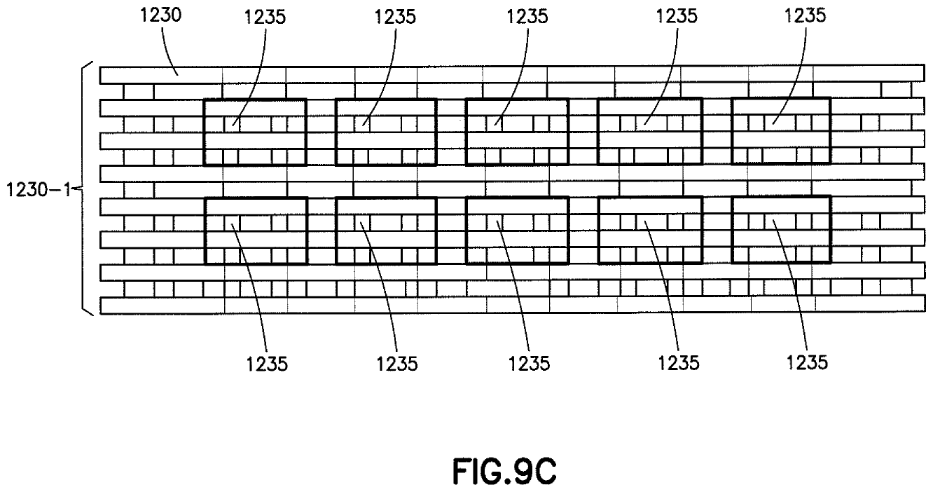

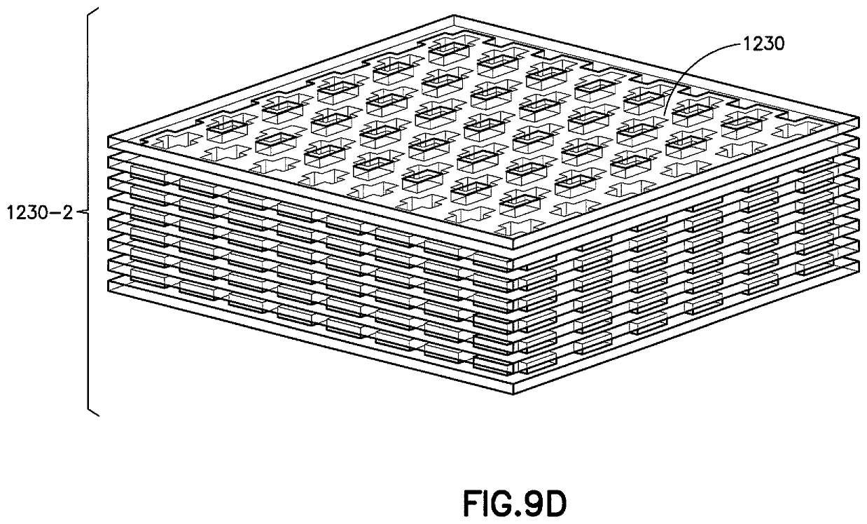

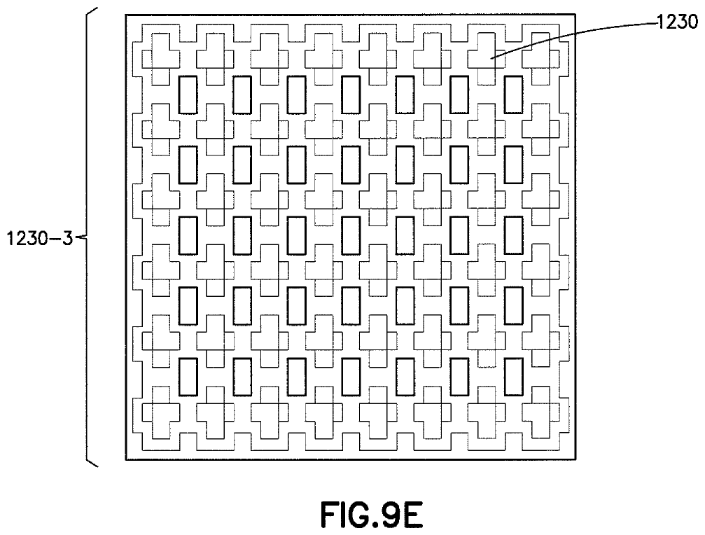

FIG. 9 depicts various schematics of the designs described herein for small node technologies, including schematics of structures having viabar heights across multiple layers. The designs shown in FIG. 9 implement a standard style crackstop viabar design having large viabar heights (in the Z direction) and thicknesses (in the Z direction), resulting in creation of larger viabar dimensions of the larger technology nodes within the BEOL dielectric stack of the thinner dielectric BEOL dielectric stack thicknesses of small technology nodes. Structure 1210 uses supervias or skipvia bars (V2, V4, V6) that span (e.g. extend through) multiple dielectric layers to connect adjacent metal layers (M1, M3, M5, M7). Structure 1220 uses supervias or skipvia bars (V2, V4, V6) that span multiple dielectric layers within the structure, which supervias or skip vias (V2, V4, V6) are interweaved between metal plates (M2, M4, M6), to connect the metal layers (M1, M3, M5, M7).

FIG. 9 further shows a schematic of a cross-sectional view (1230-1) of a structure 1230 that implements the examples described herein. Structure 1230 includes several supervia or skipvia bar structures (1235) with a height in the Z direction, and that span (e.g. extend though) multiple layers of the structure 1230 and terminate of different levels of structure 1230. The supervia or skipvia bar structures (1235) are interwoven within and through the metal plates of the structure 1230. Shown also is an isometric view (1230-2) of the structure 1230, and a top-down view (1230-3) of the structure 1230.

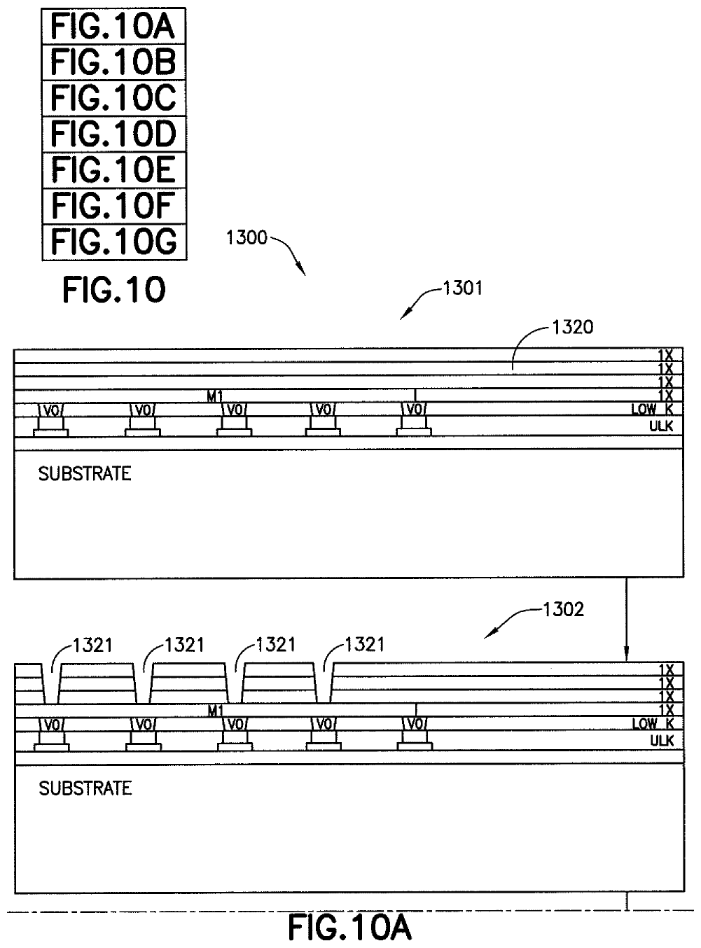

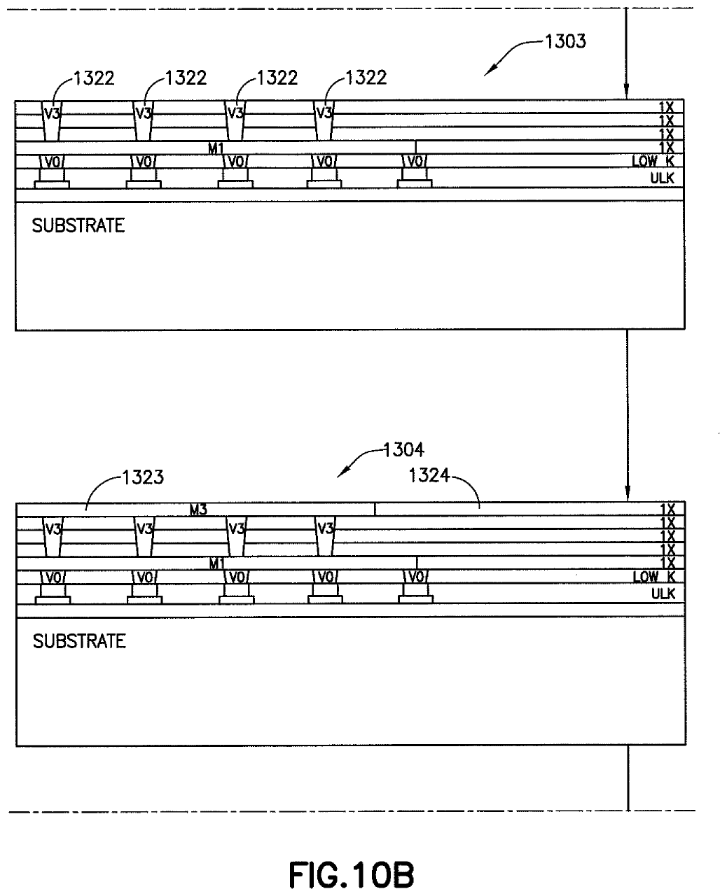

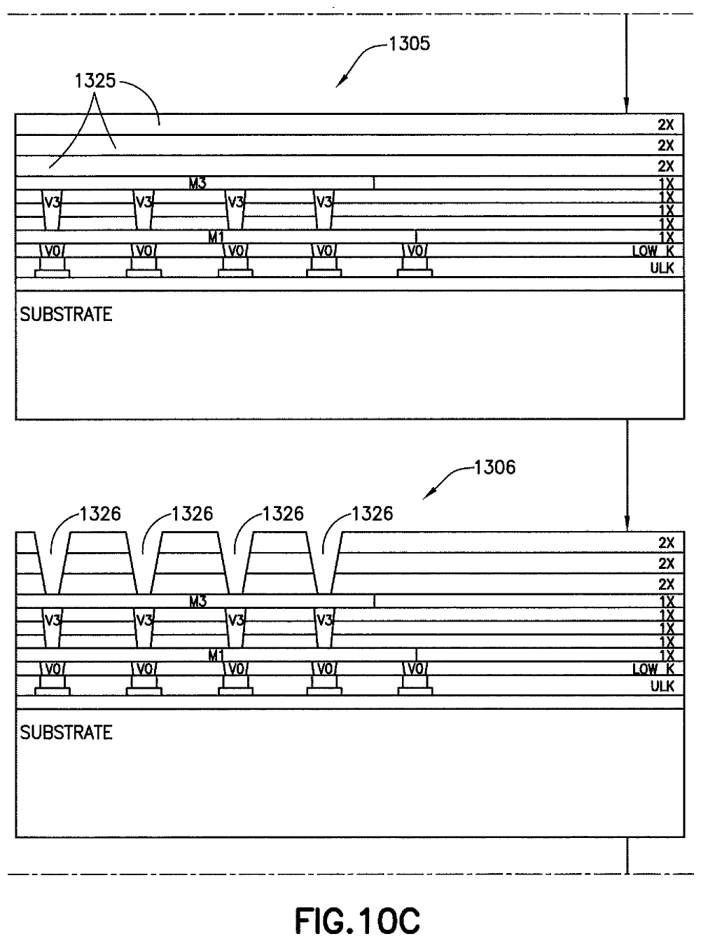

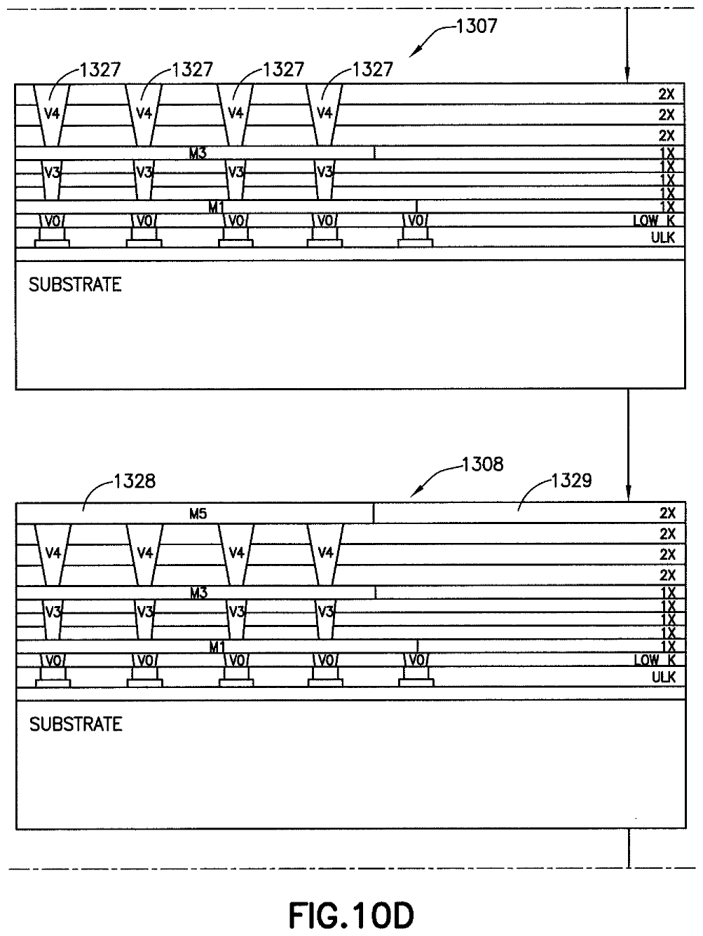

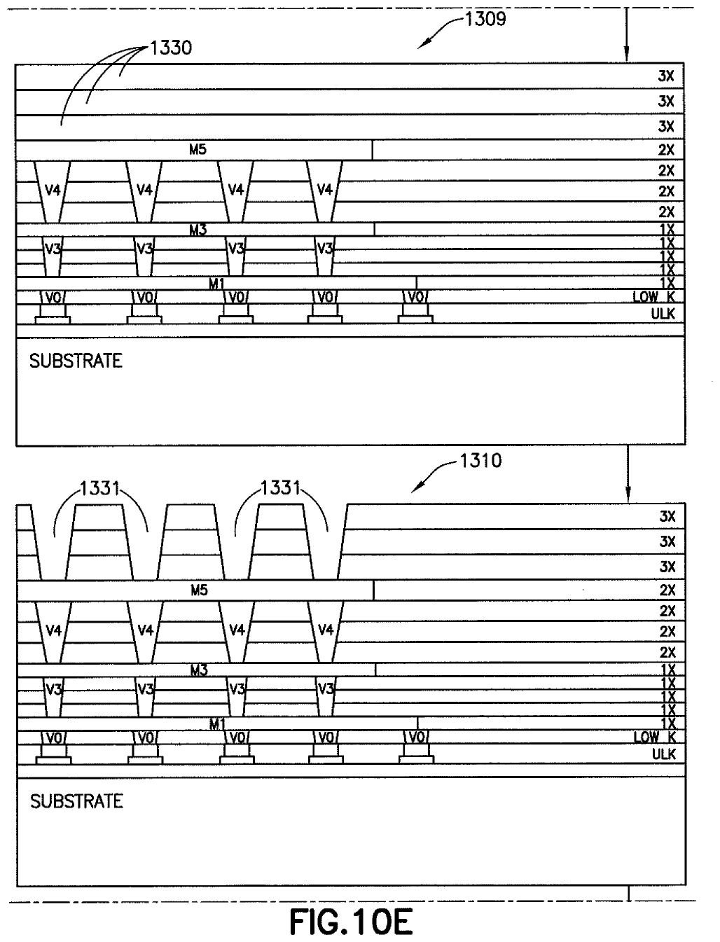

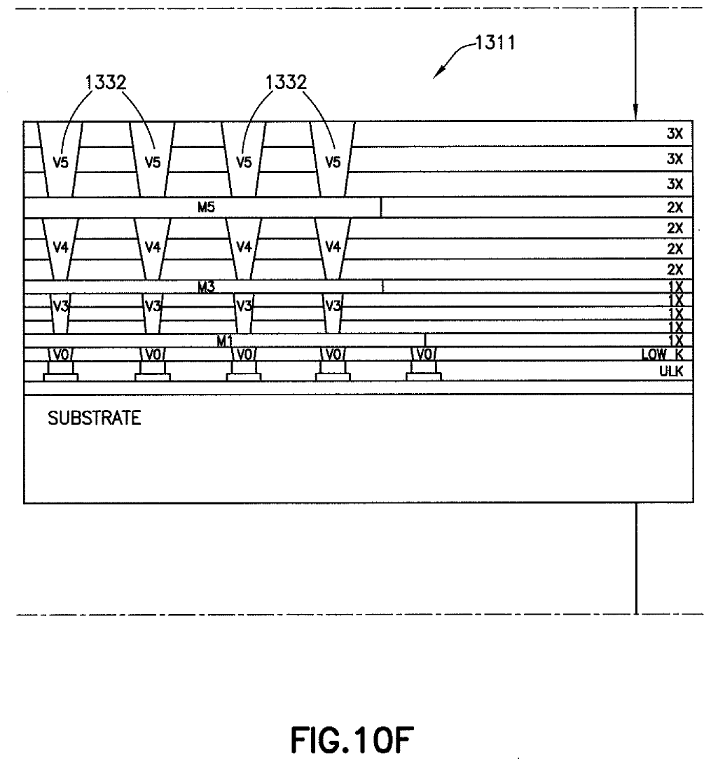

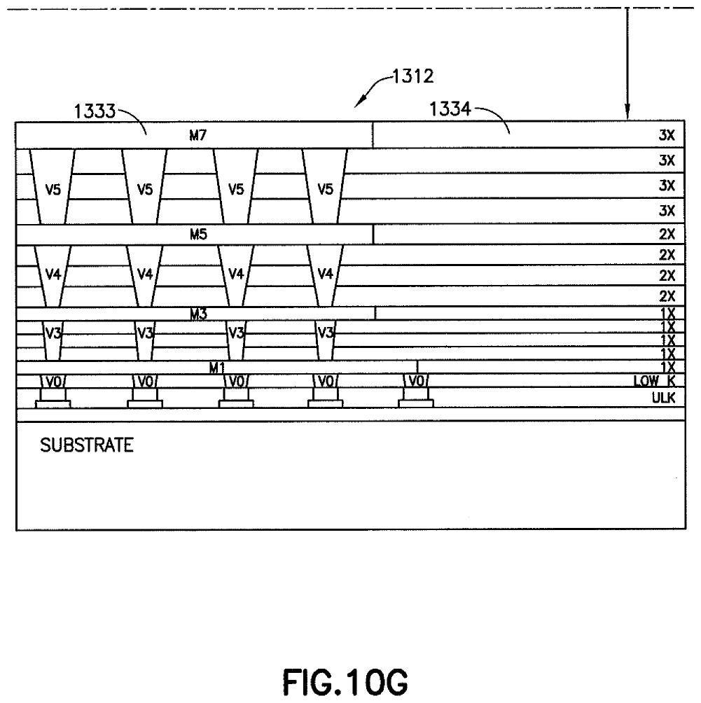

FIG. 10 shows an example process flow to form the crackstop design described herein. At 1301, the process begins with a structure 1320. At 1302, spaces (1321) are etched within a subset of the 1X-sized layers. At 1303, supervia bars (1322) are formed within the spaces (1321). At 1304, a metal layer 1323 is formed above and connects to the supervia bars (1322) formed at 1303, and an additional 1X-sized layer 1324 is formed next to the formed metal layer 1323 and above one of the 1X-sized layers.

At 1305, three 2X-sized layers (1325) are formed above metal layer 1323 and added 1X-sized layer 1324. At 1306, spaces (1326) are etched within the layers (1325). At 1307, supervia or skipvia bars (1327) are formed within spaces 1326, which vias (1327) connect to metal layer 1323. At 1308, a metal layer 1328 of size 2× is formed above and connects to the supervia bars (1327) formed at 1307, and an additional 2X-sized layer 1329 is formed next to the formed metal layer 1328 and above one of the 2X-sized layers (1325).

At 1309, three 3X-sized layers (1330) are formed above metal layer 1328 and added 2X-sized layer 1329. At 1310, spaces (1331) are etched within layers (1330). At 1311, supervia or skipvia bars (1332) are formed within spaces 1331, which via bars (1332) connect to metal layer 1328. At 1312, a metal layer 1333 of size (e.g. thickness) 3× is formed above and connects to the supervia bars (1332) formed at 1311, and an additional 3X-sized layer 1334 is formed next to the formed metal layer 1333 and above one of the 3X-sized layers (1330). In the process flow of FIG. 10, because of improved strength of the supervia bar designs, the mask can be reused, without consideration for base rules or minimum levels. Reusing the mask results in a cheaper process flow 1300.

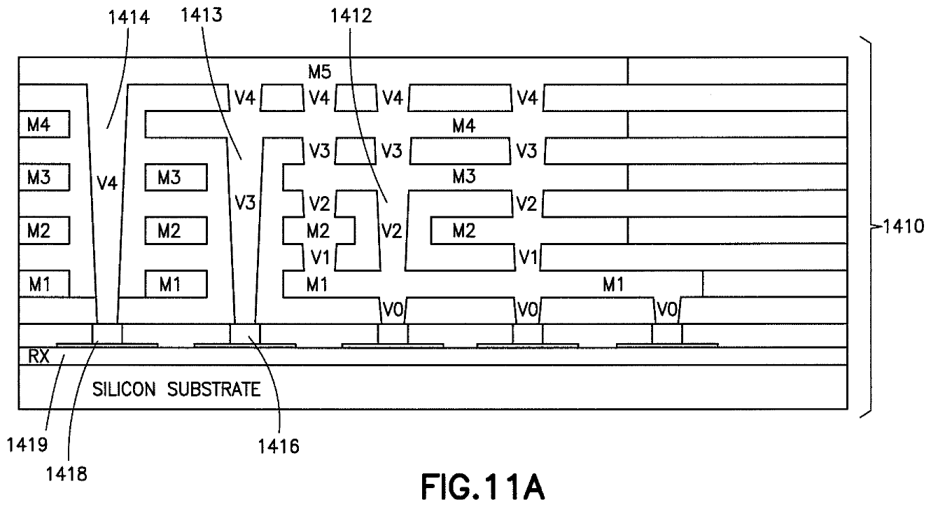

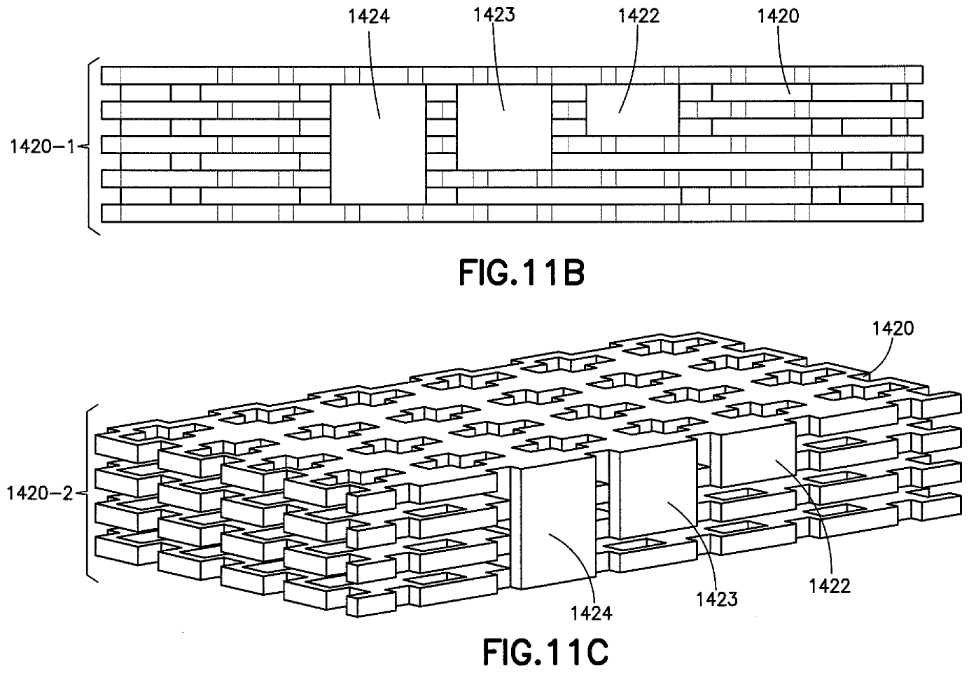

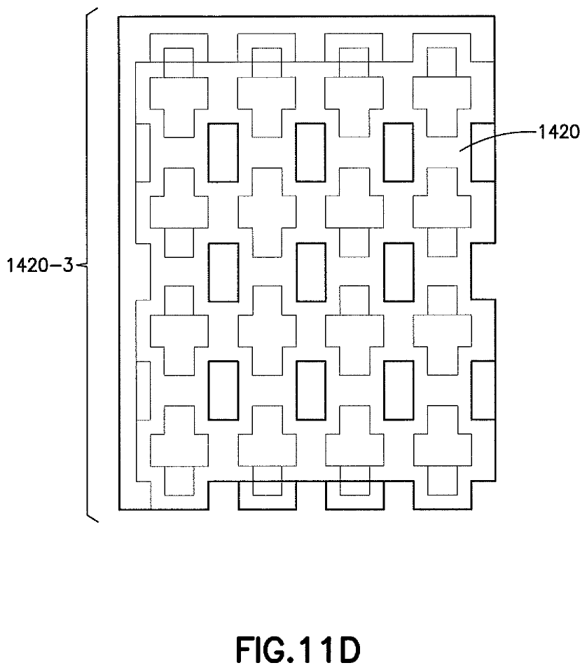

FIG. 11 depicts schematics of the designs described herein for small node technologies, including schematics of staggered structures having different viabar heights across multiple layers, where the viabars are interweaved between the metal layers. The designs shown in FIG. 11 implement multiple viabar height and termination points. Structure 1410 uses supervias or skipvia bars (1412, 1413, 1414) that span (e.g. extend through) multiple layers to connect metal layer M1 to metal layer M3, and to connect metal layers (M4, M5) to structures (1416, 1418) joined to active layer 1419.

In particular, viabar 1412 spans three layers in the vertical direction, joins metal layer M1 to metal layer M3, and is interweaved between metal plates (M2). Viabar 1413 spans eight layers in the vertical direction, joins metal layer M4 to structure 1416, and is interweaved between metal plates (M1, M2, M3). Viabar 1414 spans ten layers in the vertical direction, joins metal layer M5 to structure 1418, and is interweaved between metal plates (M1, M2, M3, M4).

FIG. 11 further shows a schematic of a cross-sectional view 1420-1 of a structure 1420 that implements multiple viabar heights and terminations. Structure 1420 includes several supervias or skipvia bars (1422, 1423, 1424) with differing heights in the Z direction, each spanning multiple layers of the structure 1420 and that may be interleaved within metal plates of the structure 1420. Shown also is an isometric view (1420-2) of the structure 1420, and a top-down view (1420-3) of the structure 1420.

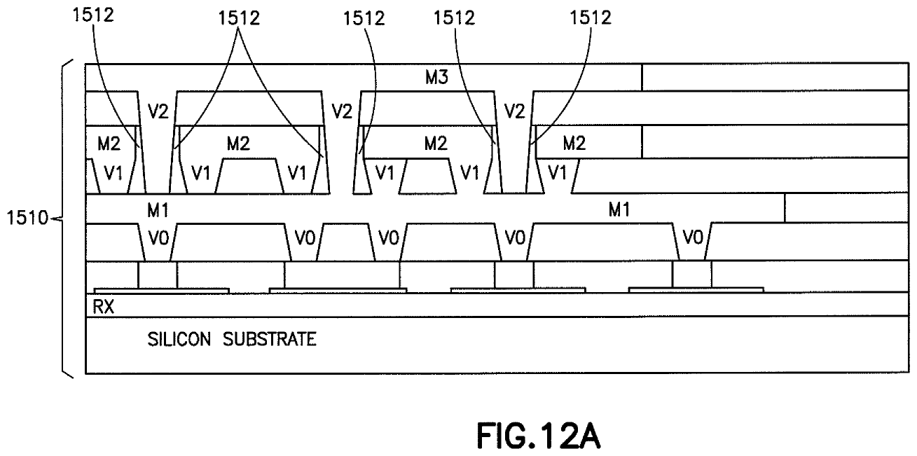

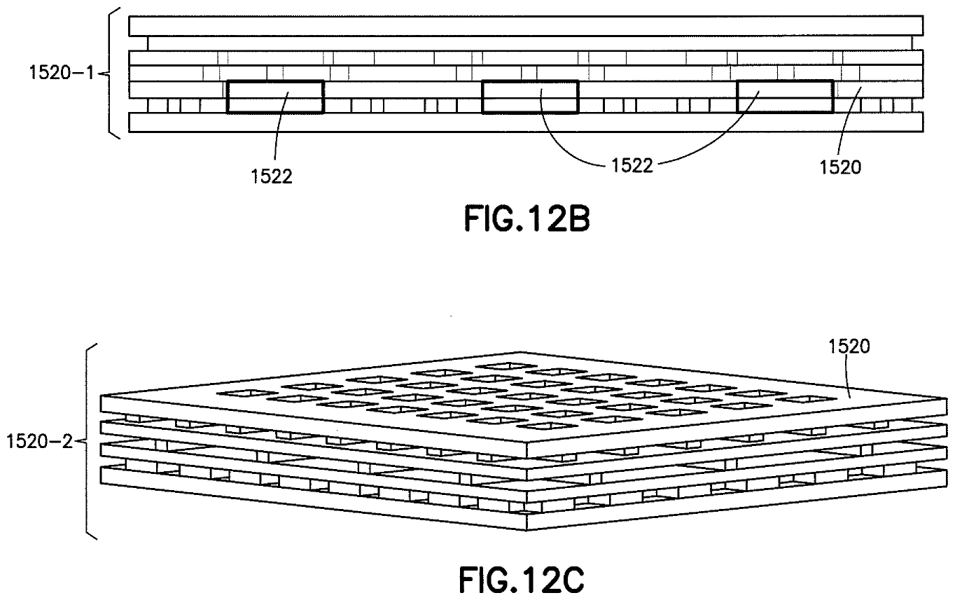

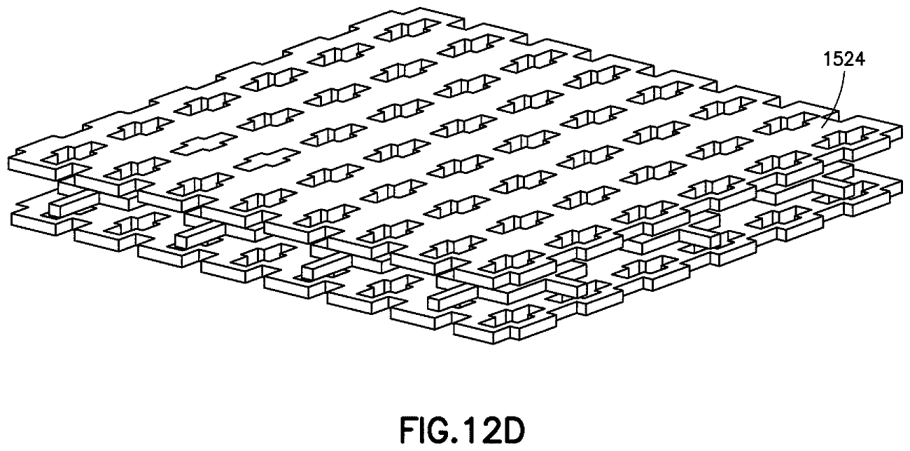

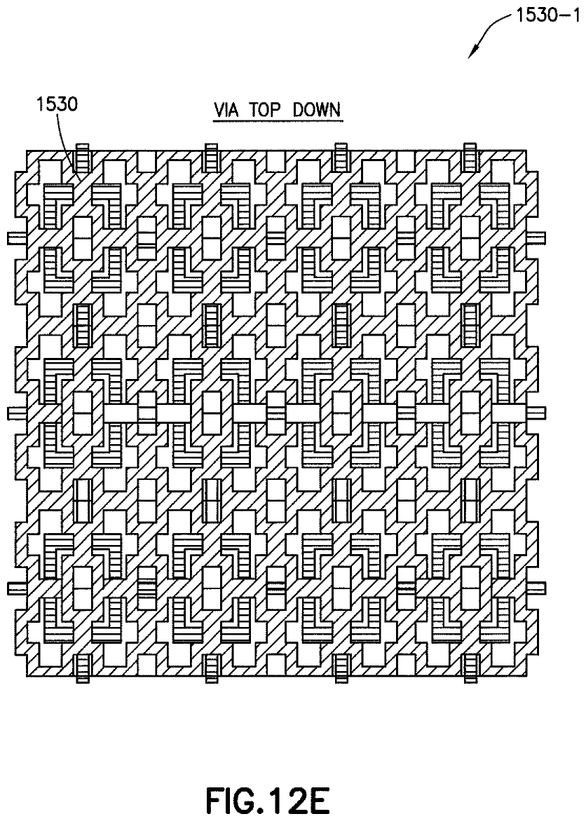

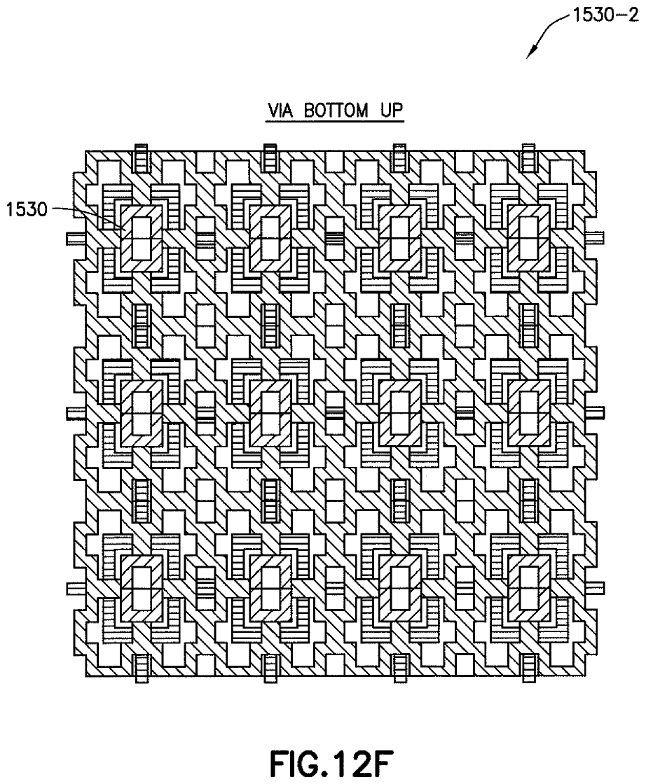

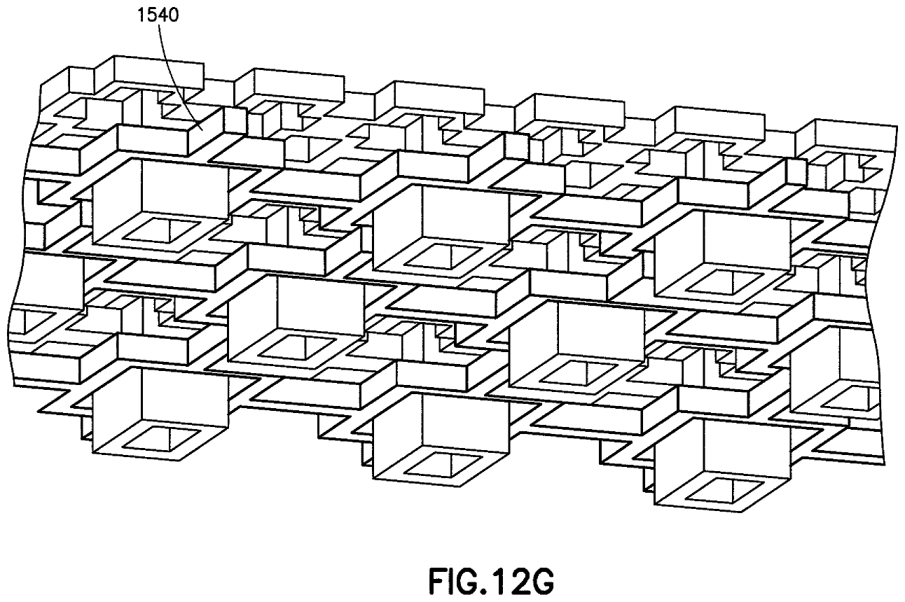

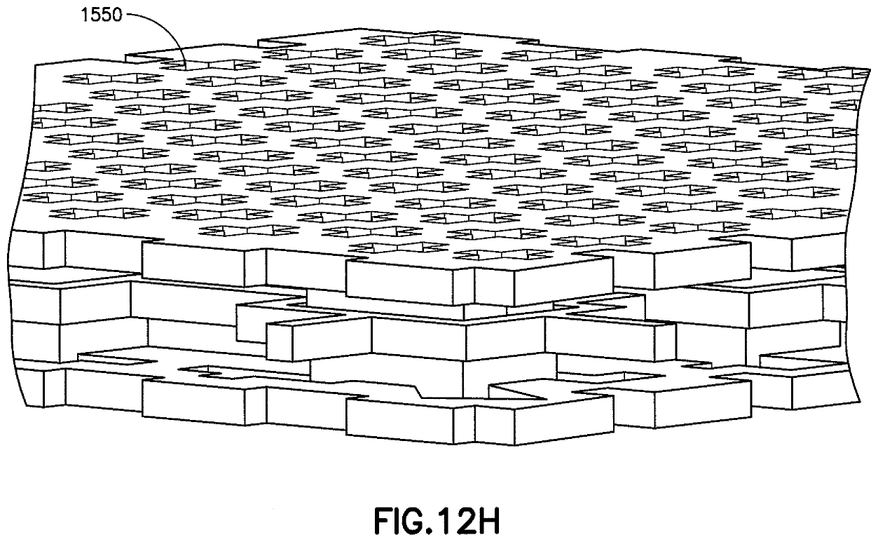

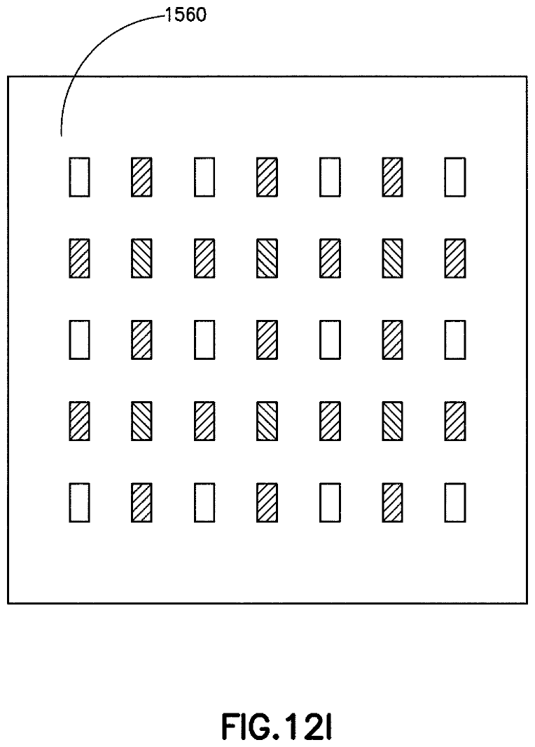

FIG. 12 depicts design schematics having a viabar through viabar pattern that forms a cage-like interwoven three-dimensional structure. In FIG. 12, the viabar pillars extend from higher levels down through holes and land on lower levels breaking up the single interface present on individual level junctions. For example in structure 1510, viabars (V2) extend from joining M3 down through holes (1512) separating the viabars (V2) from the metal layers (M2) and land on metal layer M1. FIG. 12 shows a cross-sectional view (1520-1) of a structure 1520 having viabars (1522) spanning multiple layers of the structure through holes of the structure that separate the viabars (1522) to implement an interwoven three-dimensional structure, an isometric view (1520-2) of the structure 1520, and a view of the interwoven three-dimensional structure 1524 implemented by the structure 1520.

FIG. 12 further shows a viabar top down view (1530-1) of a cage-like interwoven three-dimensional structure 1530, and a viabar bottom up view (1530-2) of the interwoven three-dimensional structure 1530. FIG. 12 further shows an isometric view of a cage-like interwoven three-dimensional structure 1540 zoomed to see that viabars are interwoven through each other, an isometric view of a cage-like interwoven three-dimensional structure 1550 zoomed to see that viabars are interwoven through each other, and a top down view of a cage-like interwoven three-dimensional structure 1560.

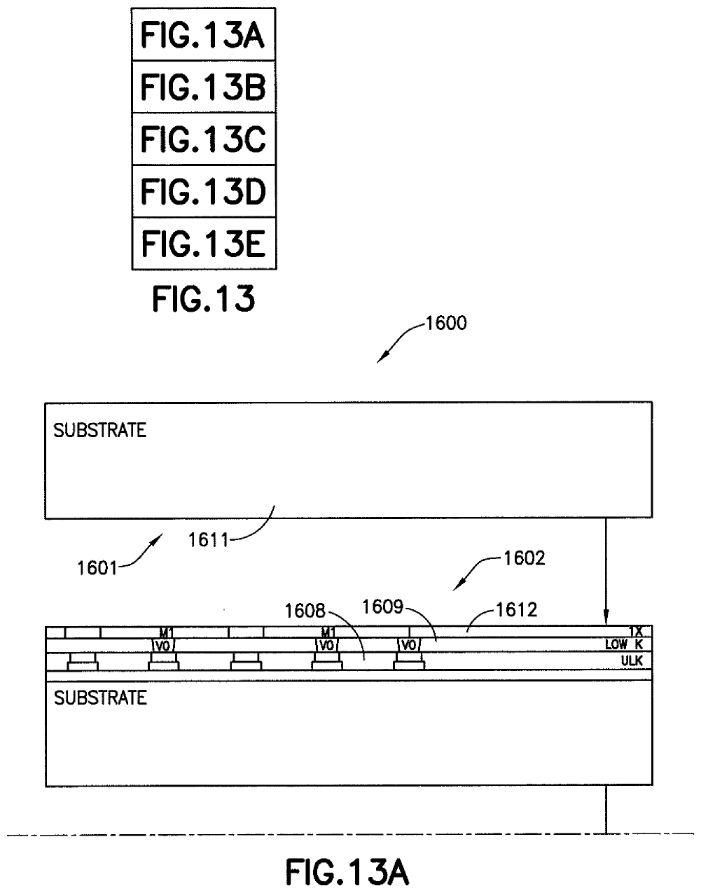

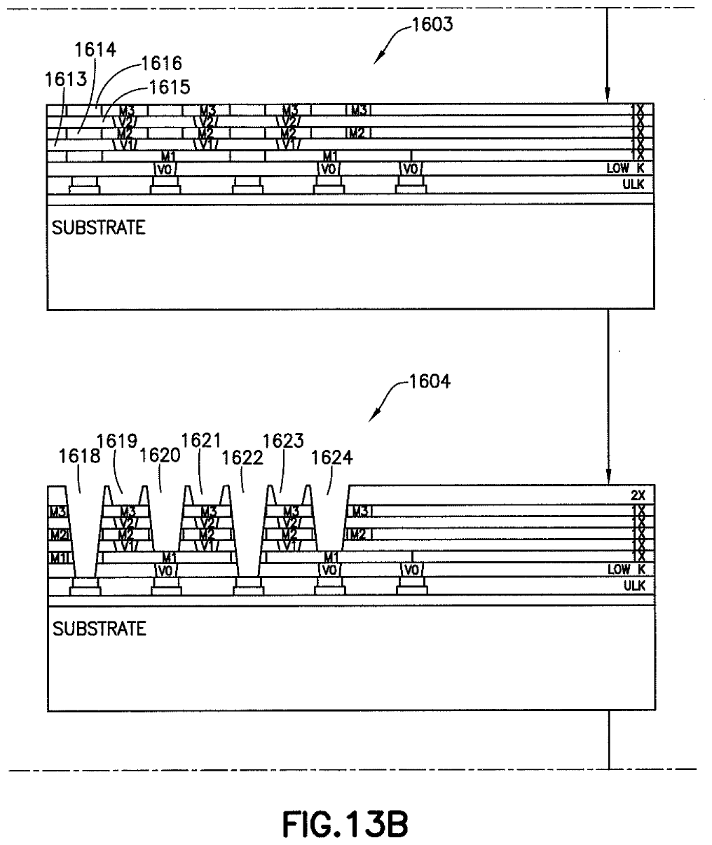

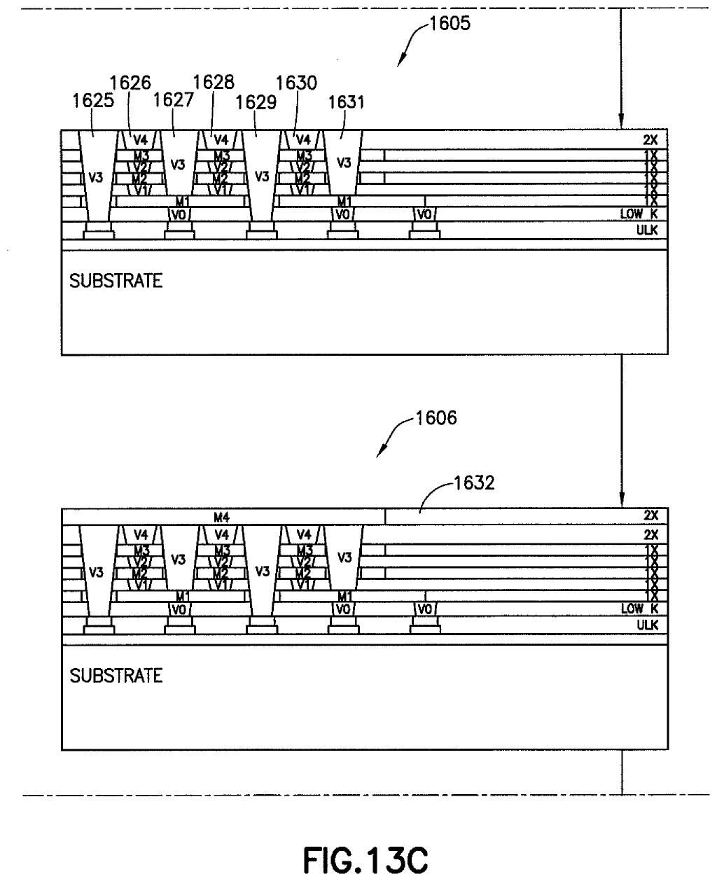

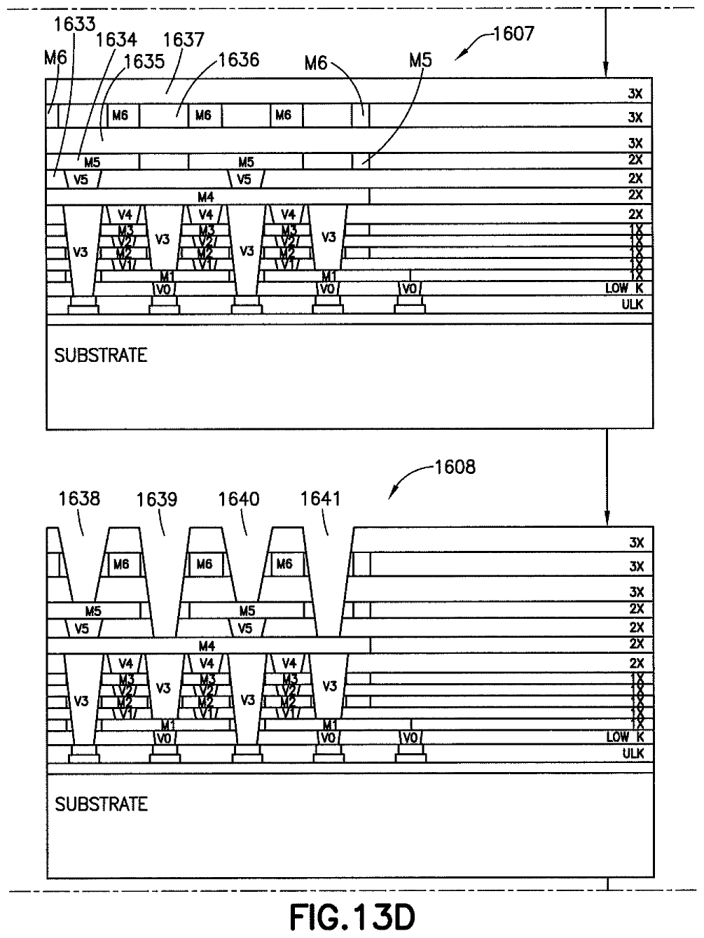

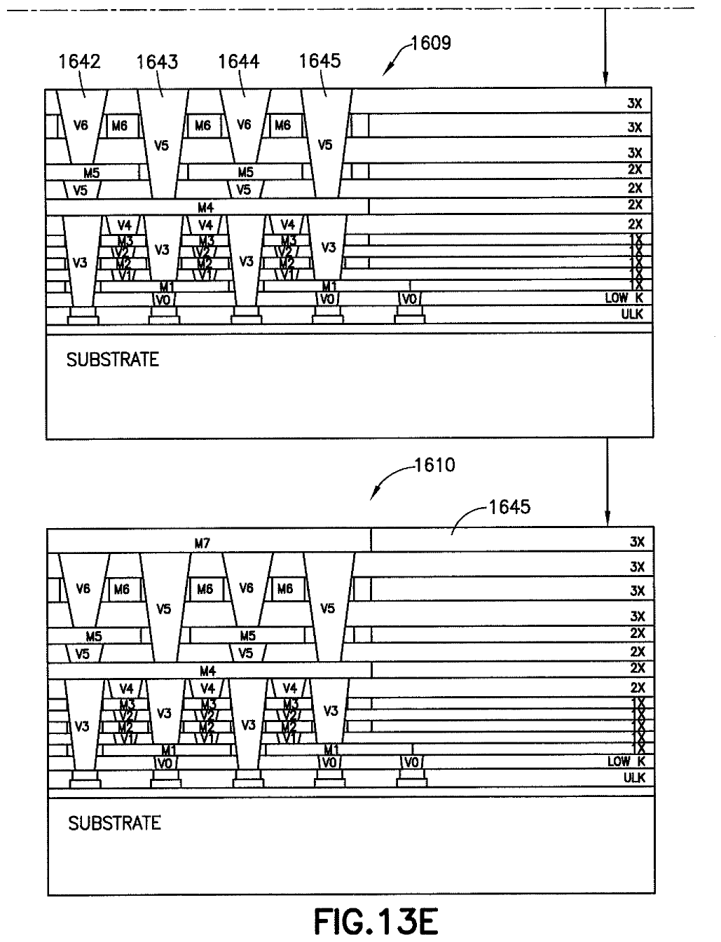

FIG. 13 is an example process 1600 to form a device having mixed viabar heights. At 1601, the process begins with substrate 1611. At 1602, a ULK layer 1608 is joined above the substrate 1611, a low-K layer 1609 having viabars is joined to structures of the ULK layer 1608, and a 1X-sized layer 1612 having metal plates (M1) is joined to the low-K layer. At 1603, 1X-sized layers (1613, 1614, 1615, 1616) are joined above layer 1612. Layer 1613 has vias joined to metal plates (M1) of layer 1612 and to metal plates M2 of layer 1614. Layer 1615 has viabars joined to metal plates M2 of layer 1614 and to metal plates M3 of layer 1616. At 1604, a 2X-sized layer 1617 is joined to layer 1616. Spaces (1618, 1622) are etched through some of the layers (1617, 1616, 1615, 1614, 1613, 1612, 1609), between the metal plates (M3) of layer 1616, metal plates (M2) of layer 1614, and metal plates (M1) of layer 1612, terminating at structures of the ULK layer 1608. Spaces (1619, 1621, 1623) are etched within the 2X-sized layer 1617, terminating at metal plates (M3) of layer 1616. Spaces (1620, 1624) are formed through some of the layers (1617, 1616, 1615, 1614, 1613), between metal plates (M3) of layer 1616 and metal plates (M2) of layer 1614, terminating at metal plates (M1) of layer 1612. At 1605, viabar 1625 is formed within space 1618, viabar 1626 is formed within space 1619, viabar 1627 is formed within space 1620, viabar 1628 is formed within space 1621, viabar 1629 is formed within space 1622, viabar 1630 is formed within space 1623, and viabar 1631 is formed within space 1624.

At 1606, a 2X-sized layer 1632 is added above layer 1617. Layer 1632 comprises a metal plate M4 which is joined to the viabars (1625, 1626, 1627, 1628, 1629, 1630, 1631) formed at item 1605. At 1607, 2X-sized layers (1633, 1634) and 3X-sized layers (1635, 1636, 1637) are formed above layer 1632. Layer 1633 comprises viabars, each viabar connecting a metal plate (M5) of layer 1634 to metal plate M4 of layer 1632. Layer 1636 has metal plates (M6) formed within layer 1636. At 1608, spaces (1638, 1640) are formed through layers (1637, 1636, 1635) between the metal plates (M6) of layer 1636 terminating at a metal plate M5 of layer 1634, and spaces (1639, 1641) are formed through layers (1637, 1636, 1635, 1634, 1633) between metal plates (M6) of layer 1636 and between the metal plates (M5) of layer 1634 terminating at a metal plate M4 of layer 1632. At 1609, viabar 1642 is formed within space 1638, viabar 1643 is formed within space 1639, viabar 1644 is formed within space 1640, and viabar 1645 is formed within space 1641. At 1610, a 3X-sized layer 1645 having a metal plate (M7) is formed above layer 1637, where the metal plate M7 is joined to the viabars (1642, 1643, 1644, 1645).

The design described herein incorporates multiple termination points in one via level of the crackstop as well as interlacing varying height viabar levels intricately and three dimensionally throughout the crackstop structure. The designs described herein are an improvement to previous crackstop designs that do not have broken up interfaces. The designs described herein intertwine and interweave designs in a variety of different ways to address the problems of previous designs. There is a correlation between increasing node technology and decreasing layer thickness. In general, crackstop designs degrade in strength with respect to decreasing layer thickness. The examples described herein have a technical effect of eliminating a direct line of sight seam that has been observed to be unzipping and resulting in failures. In contrast to the examples described herein, previous designs have single seam interfaces that are not disjointed or scattered throughout the stack in the Z direction.

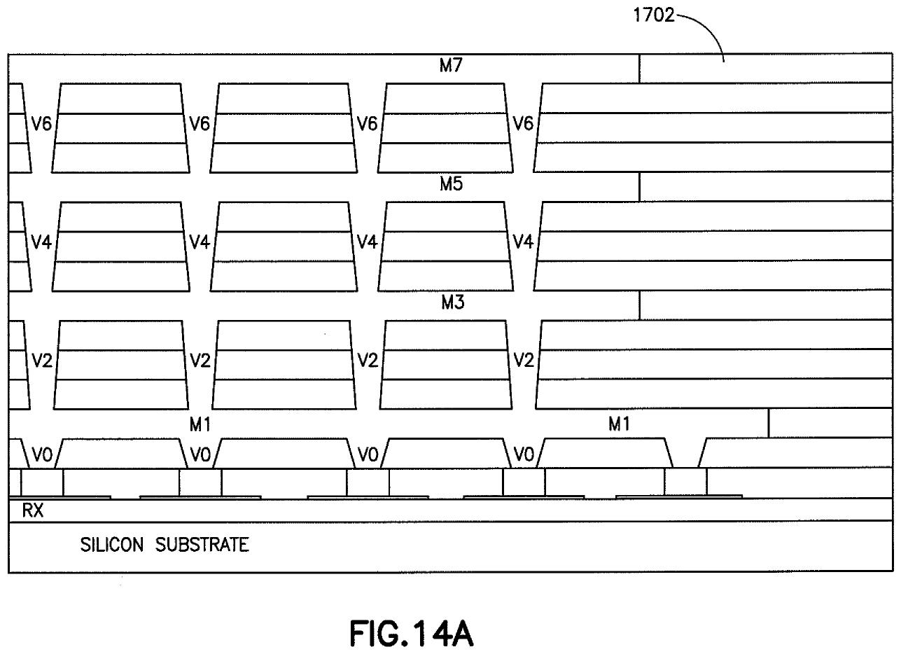

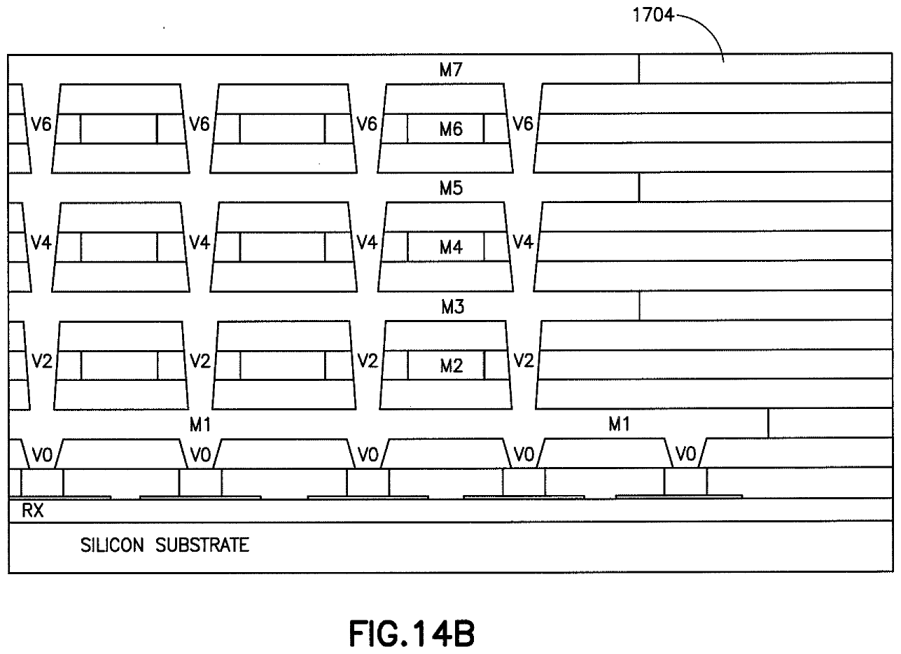

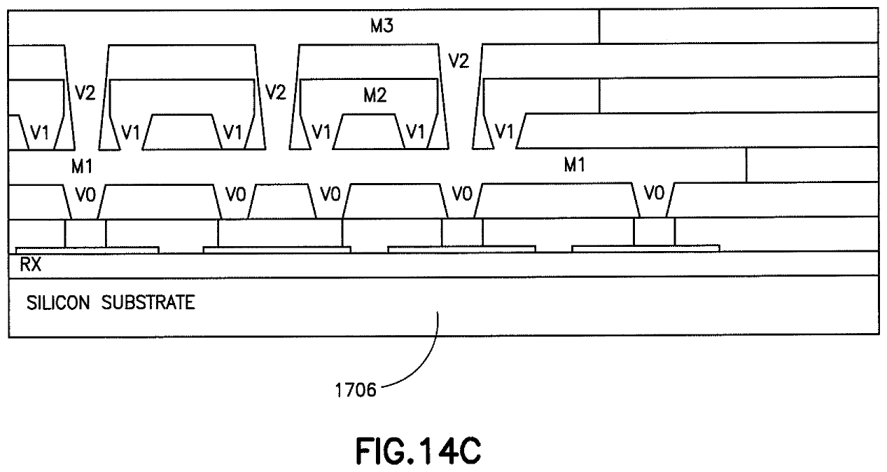

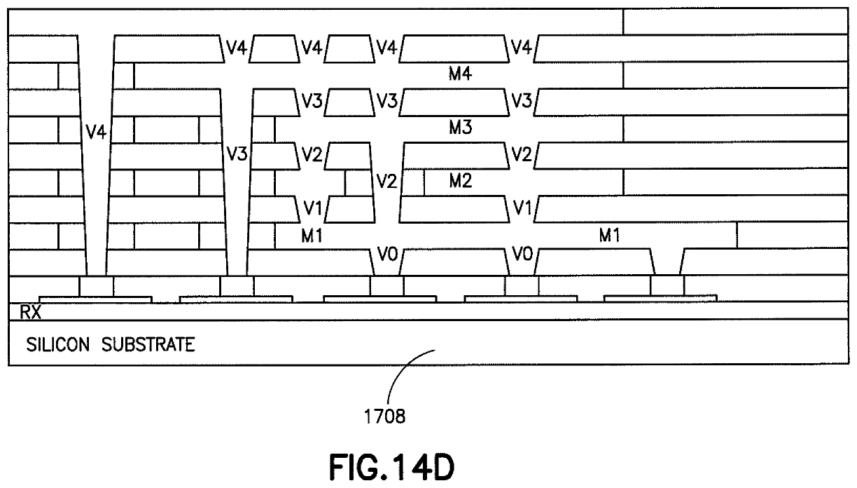

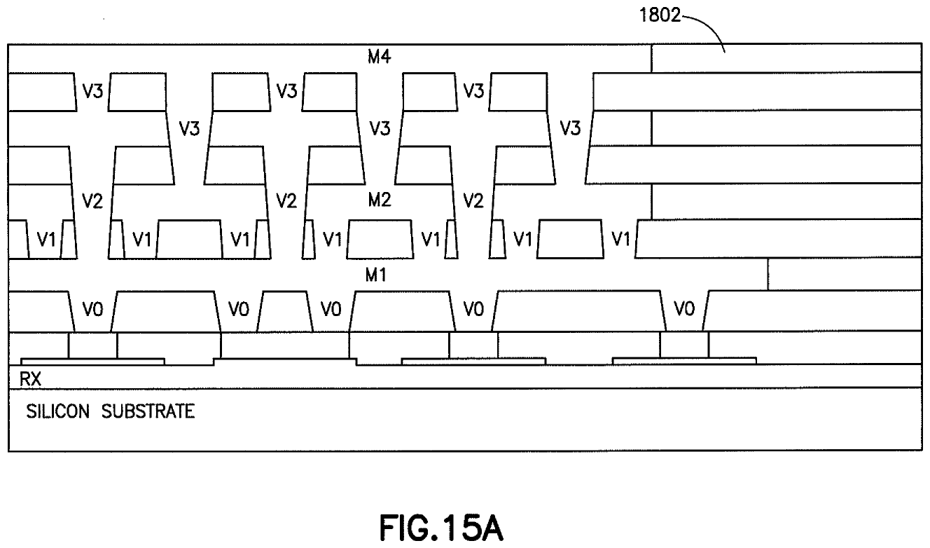

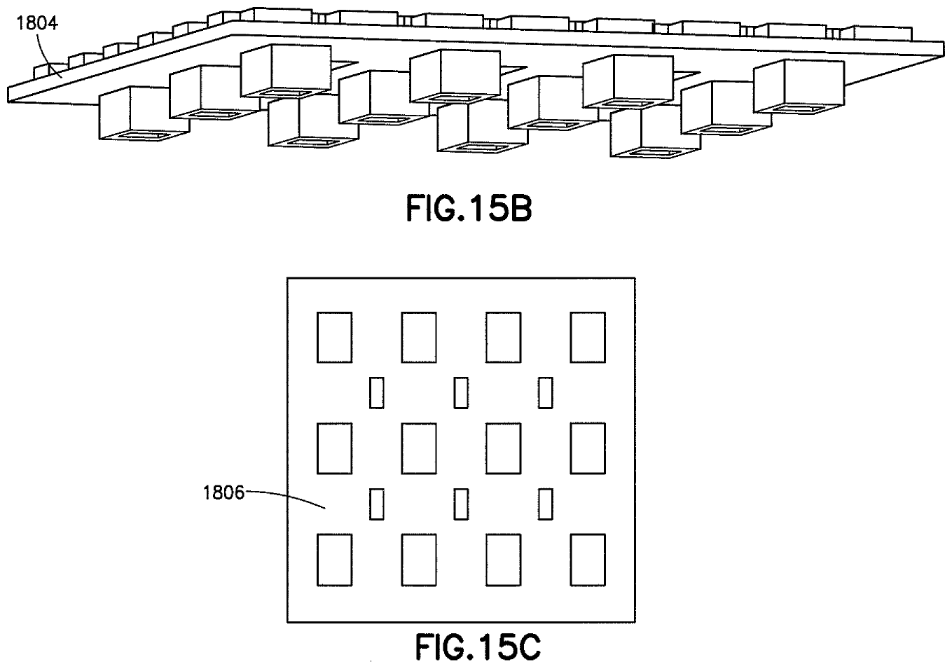

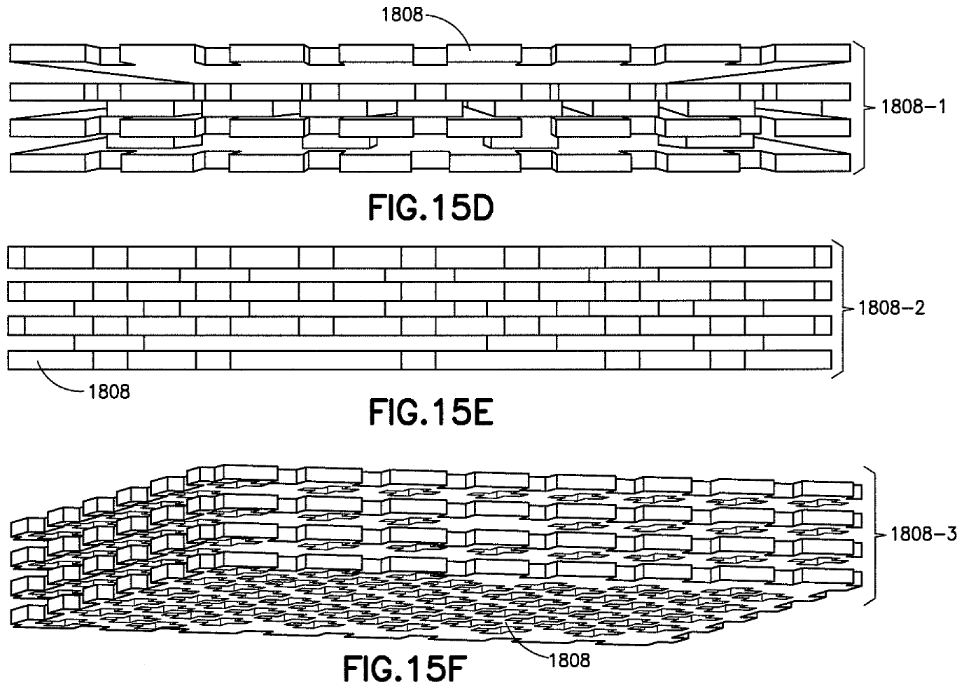

FIG. 14 shows various further examples of enhanced crackstop designs (1702, 1704, 1706, 1708), based on the examples described herein. FIG. 15 shows examples of designs for implementing an interweave crackstop cage-like interwoven three-dimensional structure, based on the examples described herein, including design 1802, an isometric view of a top portion (1804) of an interwoven three-dimensional structure, a top view of a cage-like interwoven three-dimensional structure (1806), an isometric view (1808-1) of an interwoven three-dimensional structure portion 1808 with a slight tilt from the direct side/cross sectional view, a cross-sectional view (1808-2) of the interwoven three-dimensional structure portion 1808, and an isometric view (1808-3) of the interwoven three-dimensional structure portion 1808.

There are several technical effects, benefits, and advantages of the examples described herein. The examples described herein address CPI related issues that emerge through the shrinking of the dielectric thicknesses or Z direction of a semiconductor build. The herein described interwoven structures address such issues by creating design elements that extend through multiple BEOL dielectric layers and are therefore comparable in size, strength, and robustness to that of the larger older technology node crackstop design elements. The solution described herein is therefore a stronger more robust design that emphasizes increased strength in advancing technology nodes with shrinking dielectric layer thicknesses. The herein described crackstop design and architecture has continuous interwoven viabars that start and terminate on different levels of the crackstop design. It therefore breaks up any continuous seam or line that would be made through a traditional level by level semiconductor build construction. It also creates larger stronger wall dimensions that are present in older technology nodes BEOL dielectric layers thereby obtaining the efficacy of the older better performing crackstop designs of previous generations.

The major advantage and technical effect of the herein described design over previously implemented structures is that the herein described structure is far stronger and more robust at stopping, preventing, blocking, and diverting cracks and preventing moisture ingress. By interweaving the viabar structures to start and terminate on different levels, the herein described design breaks up any seam or line that a crack could leverage to breach through a crackstop design. The larger (taller) metal plates also are stronger to their shorter counterparts. Finally having the interweave of the viabars with Z and height design elements makes the design more robust and complex for external forces to break apart, or breach.

The herein described structure is an interwoven three-dimensional continuous structure that surrounds the entire periphery of the semiconductor die builds. The structure blocks and stops crack propagation and moisture ingress from the dicing edges of the semiconductor build die. Described herein is the creation of a continuous three-dimensional interwoven metallic crackstop wall barrier that surrounds the periphery of a semiconductor die and blocks crack growth and propagation and moisture ingress from entering the prime region of the die from their respective dicing edges. The herein described structure prevents the growth and propagation progression of already nucleated nascent cracks. The interweave skipvia bar structures within the herein described crackstop structure weave through the metallic plates of the crackstop design at and through various and multiple levels of the BEOL dielectric stack of the semiconductor build, traversing those multiple levels.

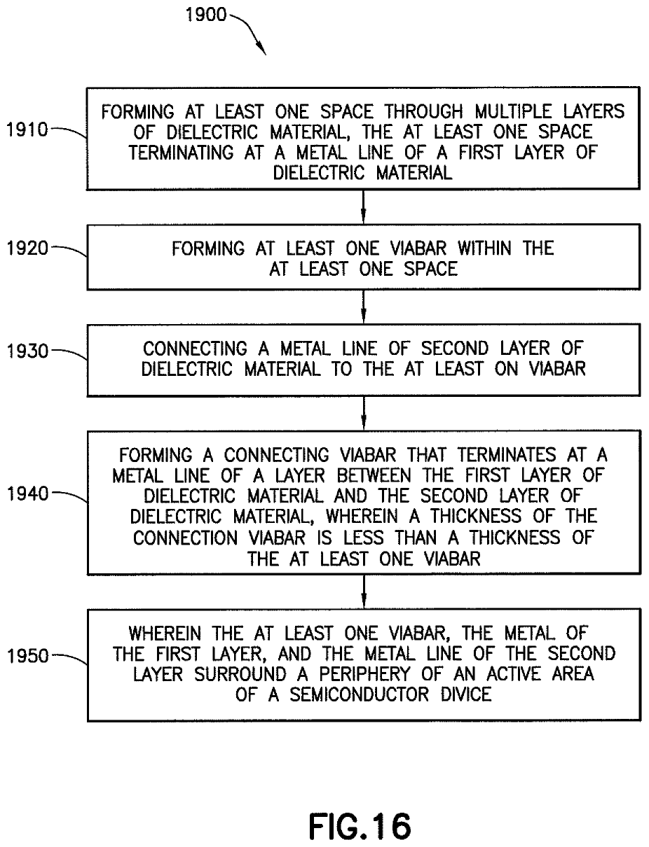

FIG. 16 is a logic flow diagram to implement a method 1900, based on the examples described herein. At 1910, the method includes forming at least one space through multiple layers of dielectric material, the at least one space terminating at a metal line of a first layer of dielectric material. At 1920, the method includes forming at least one viabar within the at least one space. At 1930, the method includes connecting a metal line of a second layer of dielectric material to the at least one viabar. At 1940, the method includes forming a connection viabar that terminates at a metal line of a layer between the first layer of dielectric material and the second layer of dielectric material, wherein a thickness of the connection viabar is less than a thickness of the at least one viabar. At 1950, the method includes wherein the at least one viabar, the metal line of the first layer, and the metal line of the second layer surround a periphery of an active area of a semiconductor device.

Referring now to all the Figures, the following examples are disclosed herein.

Example 1. A structure including: metal lines and viabars that surround a periphery of an active area of a semiconductor device; at least one viabar that extends through multiple layers of the semiconductor device, wherein the at least one viabar connects a metal line of one layer of the structure with a metal line of another layer of the structure; and a connection viabar that terminates at a metal line of a layer between the one layer of the structure and the another layer of the structure, wherein a thickness of the connection viabar is less than a thickness of the at least one viabar.

Example 2. The structure of example 1, wherein: a thickness of the metal line of the one layer is greater than a thickness of the metal line of the another layer; and a thickness of the one layer is greater than a thickness of the another layer.

Example 3. The structure of example 1, wherein the at least one viabar is between a first metal line of a first layer of the structure and a second metal line of the first layer of the structure.

Example 4. The structure of example 3, wherein the metal line of the one layer is above the first metal line of the first layer, and the metal line of the another layer is below the first metal line of the first layer.

Example 5. The structure of example 3, wherein the at least one viabar is between a first metal line of a second layer of the structure and a second metal line of the second layer of the structure.

Example 6. The structure of example 5, wherein: a thickness of the first metal line of the first layer and the second metal line of the first layer is greater than a thickness of the first metal line of the second layer and the second metal line of the second layer; and a thickness of the first layer is greater than a thickness of the second layer.

Example 7. The structure of example 6, wherein: a thickness of the metal line of the one layer is substantially the same as a thickness of the first metal line of the first layer and the second metal line of the first layer; and the thickness of the first metal line of the second layer and the second metal line of the second layer is substantially the same as a thickness of the metal line of the another layer.

Example 8. The structure of example 5, further including: at least one other viabar that extends through multiple layers of the semiconductor device, wherein the at least one other viabar connects the second metal line of the first layer of the structure to the metal line of the another layer of the structure; wherein the at least one other viabar is between the second metal line of the second layer of the structure and a third metal line of the second layer of the structure.

Example 9. The structure of example 8, wherein the at least one viabar and the at least one other viabar are staggered within the structure such that the at least one viabar extends through more layers of the structure than the at least one other viabar.

Example 10. The structure of example 1, further including: at least one other viabar that extends through multiple layers of the semiconductor device, wherein the at least one other viabar connects another metal line of the one layer of the structure with the metal line of the another layer of the structure; wherein the at least one viabar is between a first metal line of a first layer of the structure and a second metal line of the first layer of the structure; wherein the at least one other viabar is between the second metal line of the first layer of the structure and a third metal line of the first layer of the structure; wherein the metal line of the one layer and the another metal line of the one layer are above: the first metal line of the first layer, the second metal line of the first layer, and the third metal line of the first layer; wherein the metal line of the another layer of the structure is below: the first metal line of the first layer, the second metal line of the first layer, and the third metal line of the first layer.

Example 11. The structure of example 10, further including: an extension viabar that extends through multiple layers of the semiconductor device; wherein the viabar connects the second metal line of the first layer of the structure to a metal line that is in a layer above the metal line of the one layer of the structure and the another metal line of the one layer of the structure; wherein the viabar is between the metal line of the one layer of the structure and the another metal line of the one layer of the structure.

Example 12. The structure of example 11, wherein: a thickness of the metal line that is in the layer above the metal line of the one layer of the structure and the another metal line of the one layer of the structure is greater than a thickness of the second metal line of the first layer of the structure.

Example 13. A method including: forming at least one space through multiple layers of dielectric material, the at least one space terminating at a metal line of a first layer of dielectric material; forming at least one viabar within the at least one space; connecting a metal line of a second layer of dielectric material to the at least one viabar; and forming a connection viabar that terminates at a metal line of a layer between the first layer of dielectric material and the second layer of dielectric material, wherein a thickness of the connection viabar is less than a thickness of the at least one viabar; wherein the at least one viabar, the metal line of the first layer, and the metal line of the second layer surround a periphery of an active area of a semiconductor device.

Example 14. The method of example 13, further including: forming another multiple layers of dielectric material above the metal line of the second layer; forming another at least one space through the another multiple layers of dielectric material; forming another at least one viabar within the another at least one space; and connecting a metal line of a third layer of dielectric material to the another at least one viabar.

Example 15. The method of example 14, wherein: a thickness of the another multiple layers of dielectric material is greater than a thickness of the multiple layers of dielectric material; and a thickness of the metal line of the third layer of dielectric material is greater than a thickness of the metal line of the second layer of dielectric material.

Example 16. The method of example 13, wherein the at least one viabar is formed between: a first metal line of a layer that is below the metal line of the second layer of dielectric material and that is above the metal line of the first layer of dielectric material; and a second metal line of a layer that is below the metal line of the second layer of dielectric material, and that is above the metal line of the first layer of dielectric material.

Example 17. The method of example 16, further including: forming at least one other viabar that connects the second metal line of the layer that is below the metal line of the second layer of dielectric material and that is above the metal line of the first layer of dielectric material, to the metal line of the second layer of dielectric material.

Example 18. The method of example 17, wherein the at least one other viabar is formed between two metal lines of a layer that is above the second metal line of the layer below the metal line of the second layer of dielectric material and above the metal line of the first layer of dielectric material, and that is below the metal line of the second layer of dielectric material.

Example 19. The method of example 18, wherein: the two metal lines have a thickness that is substantially the same as a thickness of the metal line of the second layer of dielectric material; the thickness of the two metal lines is greater than a thickness of the metal line of the second layer of dielectric material; and the thickness of the two metal lines is greater than a thickness of the second metal line of the layer that is below the metal line of the second layer of dielectric material and above the metal line of the first layer of dielectric material.

Example 20. A mechanical crackstop barrier including viabar mesh patterns that extend across multiple back end of line layers and terminate on different metal levels so that a seam of a metal line to a viabar is staggered through a back end of line dielectric stack height.

References to a ‘computer’, ‘processor’, etc. should be understood to encompass not only computers having different architectures such as single/multi-processor architectures and sequential or parallel architectures but also specialized circuits such as field-programmable gate arrays (FPGAs), application specific circuits (ASICs), signal processing devices and other processing circuitry. References to computer program, instructions, code etc. should be understood to encompass software for a programmable processor or firmware such as, for example, the programmable content of a hardware device whether instructions for a processor, or configuration settings for a fixed-function device, gate array or programmable logic device etc.

One or more memories as described herein may be implemented using any suitable data storage technology, such as semiconductor based memory devices, flash memory, magnetic memory devices and systems, optical memory devices and systems, non-transitory memory, transitory memory, fixed memory and removable memory. The one or more memories may comprise a database for storing data.

As used herein, circuitry may refer to the following: (a) hardware circuit implementations, such as implementations in analog and/or digital circuitry, and (b) combinations of circuits and software (and/or firmware), such as (as applicable): (i) a combination of one or more processors or (ii) portions of processor(s)/software including digital signal processor(s), software, and one or more memories that work together to cause an apparatus to perform various functions, and (c) circuits, such as a microprocessor(s) or a portion of a microprocessor(s), that require software or firmware for operation, even if the software or firmware is not physically present. As a further example, as used herein, circuitry would also cover an implementation of merely a processor (or multiple processors) or a portion of a processor and its (or their) accompanying software and/or firmware. Circuitry would also cover, for example and if applicable to the particular element, a baseband integrated circuit or applications processor integrated circuit for a mobile phone or a similar integrated circuit in a server, a cellular network device, or another network device.

A list of abbreviations is as follows, which abbreviations may be appended with each other or other characters using e.g. a dash or hyphen (“-”), and may be case insensitive:
2D two-dimensional
3D three-dimensional
ASIC application-specific integrated circuit
BEOL back end of line
CPI chip-package interaction
FPGA field-programmable gate array
ILD interlayer dielectric
K relative dielectric constant (e.g. low-K)
M metal layer or plate
RIE reactive-ion etching
Rx, RX active layer
ULK ultra low-K
V via (e.g. V0)
× times (e.g. 2×)
Z Z direction or dimension in the XYZ coordinate system

In the foregoing description, numerous specific details are set forth, such as particular structures, components, materials, dimensions, processing steps, and techniques, in order to provide a thorough understanding of the exemplary embodiments disclosed herein. However, it will be appreciated by one of ordinary skill of the art that the exemplary embodiments disclosed herein may be practiced without these specific details. Additionally, details of well-known structures or processing steps may have been omitted or may have not been described in order to avoid obscuring the presented embodiments.

The description of the present invention has been presented for purposes of illustration and description, but is not intended to be exhaustive or limiting in the form disclosed. Many modifications and variations will be apparent to those of ordinary skill in the art without departing from the scope of the invention. The embodiments were chosen and described in order to best explain the principles of the invention and the practical applications, and to enable others of ordinary skill in the art to understand the invention for various embodiments with various modifications as are suited to the particular uses contemplated.

What is claimed is:

1. A structure comprising:
metal lines and viabars that surround a periphery of an active area of a semiconductor device;
at least one viabar that extends through multiple layers of the semiconductor device, wherein the at least one viabar connects a metal line of one layer of the structure with a metal line of another layer of the structure; and
a connection viabar that terminates at a metal line of a layer between the one layer of the structure and the another layer of the structure, wherein a thickness of the connection viabar is less than a thickness of the at least one viabar.

2. The structure of claim 1, wherein:
a thickness of the metal line of the one layer is greater than a thickness of the metal line of the another layer; and
a thickness of the one layer is greater than a thickness of the another layer.

3. The structure of claim 1, wherein the at least one viabar is between a first metal line of a first layer of the structure and a second metal line of the first layer of the structure.

4. The structure of claim 3, wherein the metal line of the one layer is above the first metal line of the first layer, and the metal line of the another layer is below the first metal line of the first layer.

5. The structure of claim 3, wherein the at least one viabar is between a first metal line of a second layer of the structure and a second metal line of the second layer of the structure.

6. The structure of claim 5, wherein:
a thickness of the first metal line of the first layer and the second metal line of the first layer is greater than a thickness of the first metal line of the second layer and the second metal line of the second layer; and
a thickness of the first layer is greater than a thickness of the second layer.

7. The structure of claim 6, wherein:
a thickness of the metal line of the one layer is substantially the same as a thickness of the first metal line of the first layer and the second metal line of the first layer; and
the thickness of the first metal line of the second layer and the second metal line of the second layer is substantially the same as a thickness of the metal line of the another layer.

8. The structure of claim 5, further comprising:
at least one other viabar that extends through multiple layers of the semiconductor device, wherein the at least one other viabar connects the second metal line of the first layer of the structure to the metal line of the another layer of the structure;
wherein the at least one other viabar is between the second metal line of the second layer of the structure and a third metal line of the second layer of the structure.

9. The structure of claim 8, wherein the at least one viabar and the at least one other viabar are staggered within the structure such that the at least one viabar extends through more layers of the structure than the at least one other viabar.

10. The structure of claim 1, further comprising:
at least one other viabar that extends through multiple layers of the semiconductor device, wherein the at least one other viabar connects another metal line of the one layer of the structure with the metal line of the another layer of the structure;
wherein the at least one viabar is between a first metal line of a first layer of the structure and a second metal line of the first layer of the structure;
wherein the at least one other viabar is between the second metal line of the first layer of the structure and a third metal line of the first layer of the structure;
wherein the metal line of the one layer and the another metal line of the one layer are above: the first metal line of the first layer, the second metal line of the first layer, and the third metal line of the first layer;
wherein the metal line of the another layer of the structure is below: the first metal line of the first layer, the second metal line of the first layer, and the third metal line of the first layer.

11. The structure of claim 10, further comprising:
an extension viabar that extends through multiple layers of the semiconductor device;
wherein the viabar connects the second metal line of the first layer of the structure to a metal line that is in a layer above the metal line of the one layer of the structure and the another metal line of the one layer of the structure;
wherein the viabar is between the metal line of the one layer of the structure and the another metal line of the one layer of the structure.

12. The structure of claim 11, wherein:
a thickness of the metal line that is in the layer above the metal line of the one layer of the structure and the another metal line of the one layer of the structure is greater than a thickness of the second metal line of the first layer of the structure.

13. A method comprising:
forming at least one space through multiple layers of dielectric material, the at least one space terminating at a metal line of a first layer of dielectric material;
forming at least one viabar within the at least one space;
connecting a metal line of a second layer of dielectric material to the at least one viabar; and
forming a connection viabar that terminates at a metal line of a layer between the first layer of dielectric material and the second layer of dielectric material, wherein a thickness of the connection viabar is less than a thickness of the at least one viabar;
wherein the at least one viabar, the metal line of the first layer, and the metal line of the second layer surround a periphery of an active area of a semiconductor device.

14. The method of claim 13, further comprising:
forming another multiple layers of dielectric material above the metal line of the second layer;
forming another at least one space through the another multiple layers of dielectric material;
forming another at least one viabar within the another at least one space; and
connecting a metal line of a third layer of dielectric material to the another at least one viabar.

15. The method of claim 14, wherein:
a thickness of the another multiple layers of dielectric material is greater than a thickness of the multiple layers of dielectric material; and
a thickness of the metal line of the third layer of dielectric material is greater than a thickness of the metal line of the second layer of dielectric material.

16. The method of claim 13, wherein the at least one viabar is formed between:
a first metal line of a layer that is below the metal line of the second layer of dielectric material and that is above the metal line of the first layer of dielectric material; and
a second metal line of a layer that is below the metal line of the second layer of dielectric material, and that is above the metal line of the first layer of dielectric material.

17. The method of claim 16, further comprising:
forming at least one other viabar that connects the second metal line of the layer that is below the metal line of the second layer of dielectric material and that is above the metal line of the first layer of dielectric material, to the metal line of the second layer of dielectric material.

18. The method of claim 17, wherein the at least one other viabar is formed between two metal lines of a layer that is above the second metal line of the layer below the metal line of the second layer of dielectric material and above the metal line of the first layer of dielectric material, and that is below the metal line of the second layer of dielectric material.

19. The method of claim 18, wherein:
the two metal lines have a thickness that is substantially the same as a thickness of the metal line of the second layer of dielectric material;
the thickness of the two metal lines is greater than a thickness of the metal line of the second layer of dielectric material; and
the thickness of the two metal lines is greater than a thickness of the second metal line of the layer that is below the metal line of the second layer of dielectric material and above the metal line of the first layer of dielectric material.

20. A mechanical crackstop barrier comprising viabar mesh patterns that extend across multiple back end of line layers and terminate on different metal levels so that a seam of a metal line to a viabar is staggered through a back end of line dielectric stack height.
